(19) United States
(12) Patent Application Publication
(10) Pub. No.: US 2024/0237424 A1
(43) Pub. Date: Jul. 11, 2024

(54) DISPLAY PANEL AND METHOD OF PROVIDING THE SAME

(71) Applicant: Samsung Display Co., Ltd., Yongin-si (KR)

(72) Inventor: INYOUNG JUNG, Yongin-si, (KR)

(21) Appl. No.: 18/526,023

(22) Filed: Dec. 1, 2023

(30) Foreign Application Priority Data
Jan. 5, 2023 (KR) 10-2023-0001526

(51) Int. Cl. H10K 59/122; H10K 59/12; H10K 59/131; H10K 71/60

(52) U.S. Cl. CPC H10K 59/122; H10K 59/1201; H10K 59/131; H10K 71/60

(57) ABSTRACT

A display panel includes a pixel defining layer including a pixel defining pattern, a light emitting element including an anode, a light emitting pattern and a cathode, and a partition wall which is on the pixel defining pattern, the partition wall including a side surface which defines a partition wall opening corresponding to the anode of the light emitting element. The light emitting pattern and the cathode are in the partition wall opening, and the cathode is electrically connected to the partition wall at the side surface thereof.

This application claims priority to Korean Patent Application No. 10-2023-0001526 filed on Jan. 5, 2023, and all the benefits accruing therefrom under 35 U.S.C. § 119, the disclosures of which are incorporated by reference herein in their entireties.

### BACKGROUND

### (1) Field

Embodiments of the present disclosure relate to a display panel and a method of manufacturing (or providing) a display panel. More particularly, embodiments relate to a display panel having improved display quality.

### (2) Description of the Related Art

Display devices such as televisions, monitors, smart phones, and tablet personal computers (PCs) which provide images to users include display panels which display images. Liquid crystal display panels, organic light emitting display panels, electro wetting display panels, electrophoretic display panels, and the like have been developed as the display panels.

The organic light emitting display panel may include an anode, a cathode, and a light emitting pattern. The light emitting pattern may be separated for each of light emitting areas, and the cathode may provide a common voltage to each of the light emitting areas.

### SUMMARY

Embodiments of the present disclosure provide a display panel in which a light emitting element is provided without using a metal mask and which has improved display quality, and a method of manufacturing (or providing) the same.

According to an embodiment, a display panel includes a base layer, a pixel defining film on the base layer and including a plurality of pixel defining patterns spaced apart from each other, a partition wall which is on the base layer and of which at least a portion covers a portion of each of the plurality of pixel defining patterns, and a light emitting element including an anode, a light emitting pattern, and a cathode in contact with the partition wall, where a partition wall opening overlapping the anode is defined in the partition wall, and the light emitting pattern and the cathode are arranged in the partition wall opening.

The plurality of pixel defining patterns may be arranged spaced apart from each other in a first direction and a second direction which intersects the first direction.

A separation space may be defined between the plurality of pixel defining patterns and the partition wall may fill the separation space.

One pixel defining pattern among the plurality of pixel defining patterns may surround the anode.

The one pixel defining pattern may include an inner surface and an outer surface surrounding the inner surface, the inner surface may overlap the anode, and the outer surface may not overlap the anode.

The pixel defining film may include a plurality of connection patterns which respectively connect the plurality of pixel defining patterns to each other.

The plurality of connection patterns may include the same material as that of the plurality of pixel defining patterns and may be formed through the same process as that of the plurality of pixel defining patterns.

The partition wall may include a first partition wall layer of which a portion is on a portion of the plurality of pixel defining patterns and which defines a first area of the partition wall opening, and a second partition wall layer which is on the first partition wall layer and defines a second area of the partition wall opening.

The partition wall may have an undercut shape, and the cathode may be in contact with an inner surface of the first partition wall layer defining the first area.

The pixel defining film may include an inorganic material.

According to an embodiment, a method of manufacturing (or providing) a display panel includes providing a preliminary display panel including a base layer and a first anode, a second anode, and a third anode disposed on the base layer, forming (or providing) a plurality of preliminary pixel defining patterns which cover the first anode, the second anode, and the third anode and are spaced apart from each other, forming a preliminary partition wall which covers the plurality of preliminary pixel defining patterns, etching the preliminary partition wall to form a partition wall in which a plurality of partition wall openings respectively overlapping the plurality of preliminary pixel defining patterns are defined, etching the plurality of preliminary pixel defining patterns to form a plurality of pixel defining patterns in which a plurality of light emitting openings respectively overlapping the plurality of partition wall openings are defined, and forming a light emitting pattern and a cathode in contact with the partition wall in each of the plurality of partition wall openings.

The plurality of preliminary pixel defining patterns may include a first preliminary pixel defining pattern, a second preliminary pixel defining pattern, and a third preliminary pixel defining pattern, the first preliminary pixel defining pattern may cover the first anode, the second preliminary pixel defining pattern may cover the second anode, and the third preliminary pixel defining pattern may cover the third anode.

The plurality of preliminary pixel defining patterns may be formed to be spaced apart from each other in a first direction and a second direction intersecting the first direction.

A separation space may be defined between the plurality of preliminary pixel defining patterns, and the forming of the preliminary partition wall may include forming a first preliminary partition wall layer which covers the plurality of preliminary pixel defining patterns and fills the separation space, and forming a second preliminary partition wall layer disposed on the first preliminary partition wall layer.

The method may further include forming a plurality of connection patterns which connect the plurality of preliminary pixel defining patterns, where the plurality of connection patterns may include the same material as that of the plurality of preliminary pixel defining patterns and may be formed through the same process as that of the plurality of preliminary pixel defining patterns.

According to an embodiment, a display panel including a base layer, a pixel defining film on the base layer and defining a light emitting opening, a partition wall on the pixel defining film and defining a partition wall opening corresponding to the light emitting opening, and a light emitting element including an anode, a light emitting pattern, and a cathode in contact with the partition wall and disposed in the partition wall opening, where the pixel defining film includes a plurality of pixel defining patterns in which the light emitting opening is defined, respectively, a separation space is defined between the plurality of pixel defining patterns, and the partition wall is filled in the separation space.

When viewed in a plane, one pixel defining pattern among the plurality of pixel defining patterns may have a closed curve shape surrounding the anode.

The pixel defining film may include a plurality of connection patterns which respectively connect the plurality of pixel defining patterns to each other.

The plurality of connection patterns may include the same material as that of the plurality of pixel defining patterns and may be formed through the same process as that of the plurality of pixel defining patterns.

The pixel defining film may include an inorganic material.

### BRIEF DESCRIPTION OF THE FIGURES

The above and other objects and features of the present disclosure will become apparent by describing in detail embodiments thereof with reference to the accompanying drawings.

FIG. 1A is a perspective view of a display device according to an embodiment of the present disclosure.

FIG. 1B is an exploded perspective view of the display device according to an embodiment of the present disclosure.

FIG. 2 is a cross-sectional view of a display module according to an embodiment of the present disclosure.

FIG. 3 is a plan view of a display panel according to an embodiment of the present disclosure.

FIG. 4 is an equivalent circuit diagram of a pixel according to an embodiment of the present disclosure.

FIG. 5 is an enlarged plan view of a portion of a display area of the display panel according to an embodiment of the present disclosure.

FIG. 6 is a cross-sectional view of the display panel along line I-I′ of FIG. 3.

FIG. 7 is a cross-sectional view of the display panel along line II-II of FIG. 5.

FIGS. 8A to 8M are cross-sectional views illustrating some operations of a method of manufacturing the display panel according to an embodiment of the present disclosure.

FIG. 9 is an enlarged plan view of a portion of a display area of the display panel according to an embodiment of the present disclosure.

FIG. 10 is a cross-sectional view of some of operations of the method of manufacturing the display panel along line III-III′ of FIG. 9.

### DETAILED DESCRIPTION

The invention now will be described more fully hereinafter with reference to the accompanying drawings, in which various embodiments are shown. This invention may however, be embodied in many different forms, and should not be construed as limited to the embodiments set forth herein. Rather, these embodiments are provided so that this disclosure will be thorough and complete, and will fully convey the scope of the invention to those skilled in the art.

In the present specification, the expression that a first component (or area, layer, part, portion, etc.) is “on”, “connected with”, or “coupled to” a second component means that the first component is directly on, connected with, or coupled to the second component without a third component interposed therebetween or means that a third component is interposed therebetween. In contrast, the expression that a first component (or area, layer, part, portion, etc.) is “directly on”, “directly connected with”, or “directly coupled to” a second component means that no third component is interposed therebetween.

The same reference numerals refer to the same components. Further, in the drawings, the thickness, the ratio, and the dimension of components are exaggerated for effective description of technical contents.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” The expression “and/or” includes one or more combinations which associated components are capable of defining.

Although the terms “first”, “second”, etc. may be used to describe various components, the components should not be limited by the terms. The terms are only used to distinguish one component from another component. For example, without departing from the right scope of the present disclosure, a first component may be referred to as a second component, and similarly, the second component may be also referred to as the first component. Singular expressions include plural expressions unless clearly otherwise indicated in the context. Within the Figures and the text of the disclosure, a reference number indicating a singular form of an element may also be used to reference a plurality of the singular element.

Also, the terms “under”, “below”, “on”, “above”, etc. are used to describe the correlation of components illustrated in drawings. The terms that are relative in concept are described based on a direction illustrated in drawings.

It will be understood that the terms “include”, “comprise”, “have”, etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

Terms “part” and “unit” mean a software component or hardware component that performs a specific function. The hardware component may include, for example, a field-programmable gate array (FPGA) or an application-specific integrated circuit (ASIC). The software component may refer to an executable code and/or data used by the executable code in an addressable storage medium. Thus, the software components may be, for example, an object-oriented software components, class components, and task components, and may include processes, functions, attributes, procedures, subroutines, program code segments, drivers, firmwares, microcodes, circuits, data, database, data structures, tables, arrays, or variables.

Unless otherwise defined, all terms (including technical terms and scientific terms) used in the present specification have the same meaning as commonly understood by those skilled in the art to which the present disclosure belongs. Furthermore, terms such as terms defined in the dictionaries commonly used should be interpreted as having a meaning consistent with the meaning in the context of the related technology, and should not be interpreted in overly ideal or overly formal meanings unless explicitly defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described with reference to accompanying drawings.

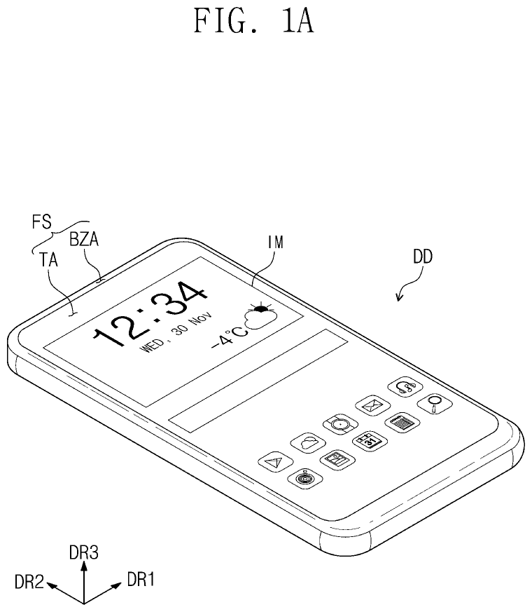

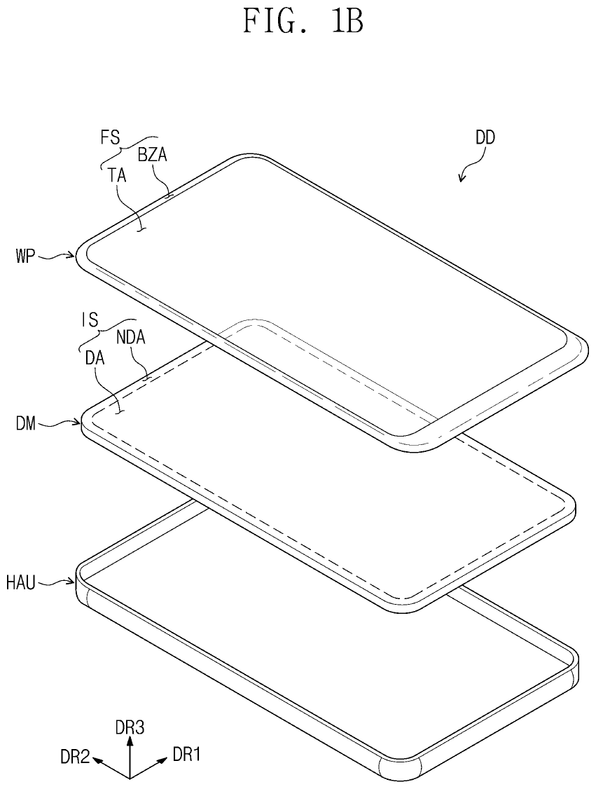

FIG. 1A is a perspective view of a display device DD according to an embodiment of the present disclosure, and FIG. 1B is an exploded perspective view of the display device DD according to an embodiment of the present disclosure.

In an embodiment, the display device DD may be a large electronic device such as a television, a monitor, or an external billboard. Further, the display device DD may be a small or medium-sized electronic device such as a personal computer (PC), a laptop, a personal digital terminal, a vehicle navigation unit, a game console, a smart phone, a tablet PC, and a camera. However, this is illustrative, and other display devices may be adopted as long as the display devices do not deviate from the concept of the present disclosure. FIGS. 1A and 1B illustrate that the display device DD is a smart phone.

Referring to FIGS. 1A and 1B, the display device DD may display an image IM in a third direction DR3 on a display surface FS parallel to a plane defined by a first direction DR1 and a second direction DR2 crossing each other. The image IM may include a still image as well as a dynamic image. In FIG. 1A, a watch window and icons are illustrated as an example of the image IM. The display surface FS on which the image IM is displayed may correspond to a front surface of the display device DD.

In an embodiment, a front surface (or an upper surface) and a rear surface (or a lower surface) of each member are defined with respect to a direction in which the image IM is displayed. The front surface and the rear surface may face each other (or be opposite to each other) in the third direction DR3, and a normal direction relative to each of the front and rear surfaces may be parallel to the third direction DR3. Directions indicated by the first to third directions DR1, DR2, and DR3 are relative concepts and may be changed to other directions. In the present specification, a phrase of “on a plane” or “in a plan view” may be meant as a state of “when viewed in (or along) the third direction DR3”.

The display device DD may include a window WP, a display module DM, and a housing HAU. The window WP and the housing HAU may be coupled to each other to constitute an exterior of the display device DD, such as to define outer (or exterior) surfaces of the display device DD.

The window WP may include an optically transparent insulating material. For example, the window WP may include a glass or plastic. A front surface of the window WP may define the display surface FS of the display device DD. The display surface FS may include a transparent area TA and a bezel area BZA. The transparent area TA may be an optically transparent area as a light transmission area. For example, the transparent area TA may be an area (e.g., a planar area along the plane defined by the first direction DR1 and the second direction DR2 crossing each other) having a visible light transmittance of about 90% or more.

The bezel area BZA may be an area having a relatively lower light transmittance than that of the transparent area TA. A planar shape of the bezel area BZA may define or correspond to a planar shape of the transparent area TA. The bezel area BZA may be adjacent to the transparent area TA. In an embodiment, the bezel area BZA may surround the transparent area TA in the plan view. However, this is illustrative, and the bezel area BZA of the window WP may be omitted such that the light transmission area extends to outer edges of the display device DD in the plan view.

The window WP may include at least one functional layer of a fingerprint prevention layer, a hard coating layer, and a reflection prevention layer, and is not limited to an embodiment.

The display module DM may be disposed below the window WP, such as to face the window WP. The display module DM may be a component or a collection of layers that substantially generates the image IM. The image IM generated by the display module DM is displayed on a display surface IS of the display module DM and is visually recognized from outside the display device DD such as by a user, through the transparent area TA.

The display module DM may include a display area DA and a non-display area NDA. The display area DA may be an area that is activated according to an electric signal. The display area DA which is activated may generate light, may emit light, may display the image IM, etc. The non-display area NDA may be adjacent to the display area DA. In an embodiment, the non-display area NDA may surround the display area DA in the plan view. The non-display area NDA is an area covered by (or corresponding to) the bezel area BZA and may not be visually recognized from the outside of the display device DD. Various components or layers of the display device DD may include or define a transparent area TA, a bezel area BZA, a display area DA, a non-display area NDA, etc. respectively corresponding to those described above.

The housing HAU may be coupled to the window WP. The housing HAU may be coupled to the window WP to provide a predetermined inner space of the display device DD in which components or layers of the display device DD are accommodated. The display module DM may be accommodated in the inner space of the display device DD.

The housing HAU may include a material having a relatively high rigidity. For example, the housing HAU may include a plurality of frames and/or plates made of or including glass, plastic, or metal or combinations thereof. The housing HAU may stably protect components of the display device DD accommodated in the inner space from an external impact.

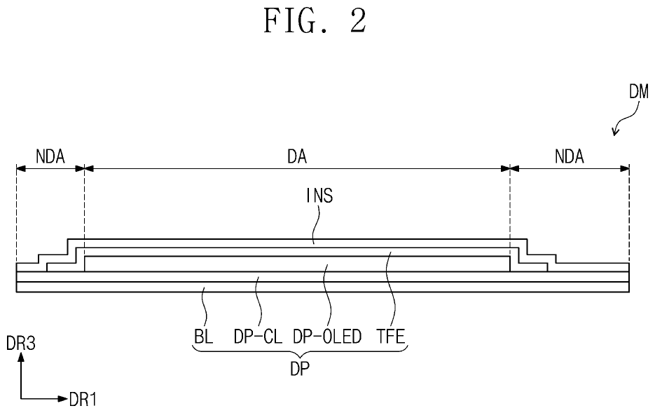

FIG. 2 is a cross-sectional view of the display module DM according to an embodiment of the present disclosure.

Referring to FIG. 2, the display module DM may include a display panel DP and an input sensor INS. Although not separately illustrated, the display device DD (see FIG. 1A) according to an embodiment of the present disclosure may further include a protective member disposed on a lower surface of the display panel DP or a reflection prevention member and/or a window member disposed on an upper surface of the input sensor INS.

The display panel DP may be a light emitting display panel. However, this is illustrative, and the present disclosure is not particularly limited thereto. For example, the display panel DP may be an organic light emitting display panel or an inorganic light emitting display panel. A light emitting layer in the organic light emitting display panel may include an organic light emitting material. A light emitting layer in the inorganic light emitting display panel may include a quantum dot, a quantum rod, or a micro light emitting diode (LED). Hereinafter, the display panel DP will be described as the organic light emitting display panel.

The display panel DP may include a base layer BL, and a circuit element layer DP-CL, a display element layer DP-OLED and a thin film encapsulation layer TFE as an encapsulation layer, which are arranged in order on the base layer BL. The input sensor INS may be directly disposed on the thin film encapsulation layer TFE. In the present specification, the wording “component A is directly disposed on component B” means that no intervening element such as adhesive layer is disposed between component A and component B.

The base layer BL may include at least one plastic film. The base layer BL may be a flexible substrate and may include a plastic substrate, a glass substrate, a metal substrate, or an organic/inorganic composite material substrate. The display area DA and the non-display area NDA described in FIG. 1B may be equally defined on the base layer BL.

The circuit element layer DP-CL may include at least one insulating layer and a circuit element. The insulating layer includes at least one inorganic layer and at least one organic layer. The circuit element includes signal lines, a driving circuit of a pixel PX, and the like.

The display element layer DP-OLED may include a partition wall and a light emitting element ED. The light emitting element ED may include an anode AE, an intermediate layer, and a cathode CE. The display element layer DP-OLED may be connected to the circuit element layer DP-CL, such as being electrically connected thereto.

The thin film encapsulation layer TFE may include a plurality of thin films. Some thin films may be arranged to improve optical efficiency, and some thin films may be arranged to protect organic light emitting diodes.

The input sensor INS acquires coordinate information of an external input. The input sensor INS may have a multilayer structure. The input sensor INS may include a single layered or multi-layered conductive layer. Further, the input sensor INS may include a single layered or multi-layered insulating layer. The input sensor INS may detect an external input in a capacitive manner. However, this is illustrative, and the present disclosure is not limited thereto. For example, in an embodiment, the input sensor INS may also detect an external input in an electromagnetic induction manner or a pressure sensing manner. In an embodiment of the present disclosure, the input sensor INS may be omitted.

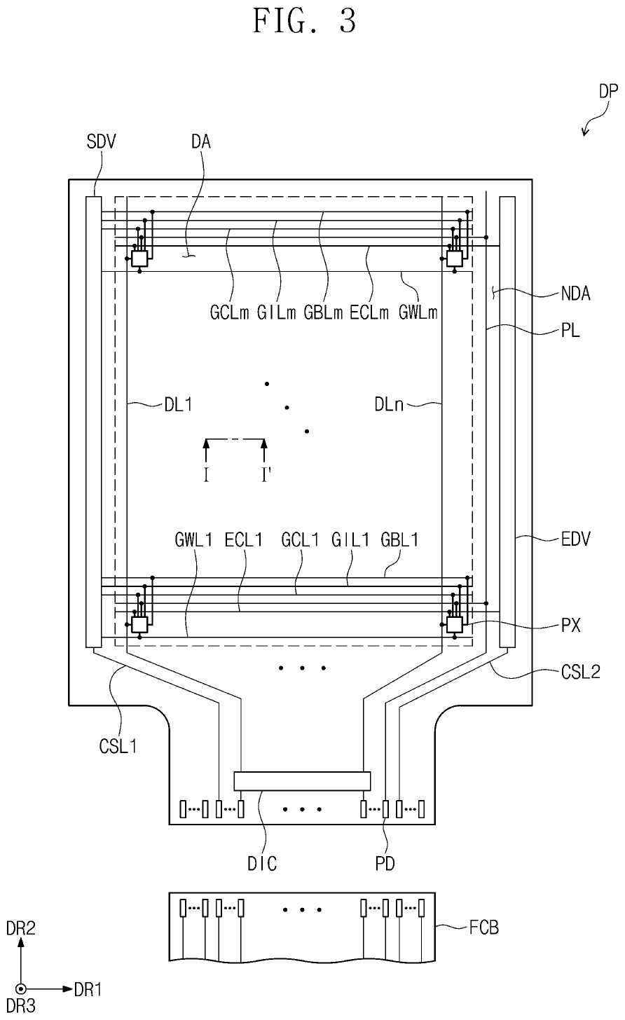

FIG. 3 is a plan view of the display panel DP according to an embodiment of the present disclosure.

Referring to FIG. 3, the display area DA and the non-display area NDA which extends along an outer edge of the display area DA may be defined by the display panel DP. The display area DA and the non-display area NDA may be distinguished depending on where a pixel PX is disposed. The pixel PX may be disposed in the display area DA. A scan driving unit SDV as a scan driver, a data driving unit as a data driver, and a light emitting driving unit EDV as a light emitting driver may be arranged in the non-display area NDA. The data driving unit may be a portion of a circuit included in a driving chip DIC.

The display panel DP may include the pixels PX, initialization scan lines GIL1 to GILm, compensation scan lines GCL1 to GCLm, write scan lines GWL1 to GWLm, black scan lines GBL1 to GBLm, light emitting control lines ECL1 to ECLm, data lines DL1 to DLn, first and second control lines CSL1 and CSL2, a driving voltage line PL, and a plurality of pads PD. In this case, “m” and “n” are natural numbers greater than or equal to two. One or more of the above-described lines and pads PD may be a signal line through which an electrical signal is transmitted.

The pixels PX may be variously connected to the initialization scan lines GIL1 to GILM, the compensation scan lines GCL1 to GCLm, the write scan lines GWL1 to GWLm, the black scan lines GBL1 to GBLm, the light emitting control lines ECL1 to ECLm, and the data lines DL1 to DLn.

The initialization scan lines GIL1 to GILM, the compensation scan lines GCL1 to GCLm, the write scan lines GWL1 to GWLm, and the black scan lines GBL1 to GBLm may extend in the first direction DR1 and may be electrically connected to the scan driving unit SDV. The data lines DL1 to DLn may extend in the second direction DR2 and may be electrically connected to the driving chip DIC. The light emitting control lines ECL1 to ECLm may extend in the first direction DR1 and may be electrically connected to the light emitting driving unit EDV.

The driving voltage line PL may include a first line portion extending in the first direction DR1 and a second line portion which extends in the second direction DR2. The line portion extending in the first direction DR1 and the line portion extending in the second direction DR2 may be arranged in different layers. The driving voltage line PL may provide a driving voltage as an electrical signal to the pixels PX.

The first control line CSL1 may be connected to the scan driving unit SDV. The second control line CSL2 may be connected to the light emitting driving unit EDV.

The driving chip DIC, the driving voltage line PL, the first control line CSL1, and the second control line CSL2 may be electrically connected to one or more of a pad PD among the plurality of pads PD. A flexible circuit film FCB as a circuit board may be electrically connected to the pads PD through a conductive member such as an anisotropic conductive adhesive layer. The pads PD may be terminal pads at which the display panel DP is connected to an external component such as the flexible circuit film FCB. The pads PD in the non-display area NDA may be connected to the corresponding pixels PX of the display area DA, through the driving voltage line PL, the first control line CSL1, and the second control line CSL2.

Further, the pads PD may further include input pads. The input pads may be pads at which the input sensor INS (see FIG. 2) is connected to the flexible circuit film FCB. However, the present disclosure is not limited thereto, and the input pads may be arranged on the input sensor INS to be a part of the input sensor INS, and connected to the pads PD of the display panel DP and a separate circuit board. Alternatively, the input sensor INS may be omitted and may not further include the input pads.

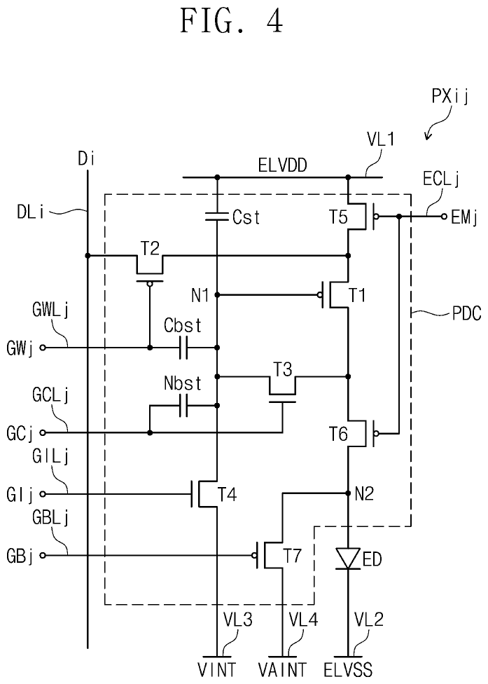

FIG. 4 is an equivalent circuit diagram of a pixel PXij according to an embodiment of the present disclosure.

FIG. 4 exemplarily illustrates an equivalent circuit diagram of one pixel Pxij among the plurality of pixels PX (see FIG. 3). Since the plurality of pixels PX have the same circuit structure, a detailed description of the other pixels PX will be omitted because a description of a circuit structure of the pixel Pxij is present.

Referring to FIGS. 3 and 4, the pixel Pxij is connected to an i^{th} data line Dli among the data lines DL1 to DLn, a j^{th} initialization scan line GILj among the initialization scan lines GIL1 to GILm, a j^{th} compensation scan line GCLj among the compensation scan lines GCL1 to GCLm, a j^{th} write scan line GWLj among the write scan lines GWL1 to GWLm, a j^{th} black scan line GBLj among the black scan lines GBL1 to GBLm, a j^{th} light emitting control line ECLj among the light emitting control lines ECL1 to ECLm, first and second driving voltage lines VL1 and VL2, and first and second initialization voltage lines VL3 and VL4. Here, ‘i’ is an integer greater than or equal to 1 and less than or equal to ‘n’, and ‘j’ is an integer greater than or equal to 1 and less than or equal to ‘m’.

The pixel Pxij includes a light emitting element ED and a pixel circuit PDC (indicated by the dotted line in FIG. 4). The light emitting element ED may be a light emitting diode. As an example of the present disclosure, the light emitting element ED may be an organic light emitting diode including an organic light emitting layer, but the present disclosure is not particularly limited thereto. The pixel circuit PDC may control the amount of an electrical current flowing in the light emitting element ED in response to a data signal Di as an electrical signal. The light emitting element ED may emit light having a predetermined luminance to correspond to the amount of electrical current provided from the pixel circuit PDC.

The pixel circuit PDC may include first to seventh transistors T1, T2, T3, T4, T5, T6, and T7, and first to third capacitors Cst, Cbst, and Nbst. According to the present disclosure, a configuration of the pixel circuit PDC is not limited to an embodiment illustrated in FIG. 4. The pixel circuit PDC illustrated in FIG. 4 is merely an example, and a configuration of the pixel circuit PDC may be modified and implemented.

At least one of the first to seventh transistors T1, T2, T3, T4, T5, T6, and T7 may be a transistor having a low-temperature polycrystalline silicon (LTPS) semiconductor layer. At least one of the first to seventh transistors T1, T2, T3, T4, T5, T6, and T7 may be a transistor having an oxide semiconductor layer. For example, the third and fourth transistors T3 and T4 may be oxide semiconductor transistors, and the first, second, fifth, sixth, and seventh transistors T1, T2, T5, T6, and T6 may be LTPS transistors.

In detail, the first transistor T1, which directly affects the brightness of the light emitting element ED, includes a highly reliable polycrystalline silicon semiconductor layer, and therefore, a high-resolution display device may be implemented. Since the oxide semiconductor has high (electrical) carrier mobility and low leakage current, a voltage drop is not large even when a driving time is long. That is, since a change in a color of the image due to the voltage drop is not large even during low-frequency driving, the low-frequency driving may be performed. In this way, since the oxide semiconductor has a low leakage current, at least one among the third transistor T3 and the fourth transistor T4 connected to a gate electrode of the first transistor T1 may be adopted as the oxide transistor, and thus leakage current that may flow to the gate electrode may be prevented, and at the same time, power consumption may be reduced.

Some of the first to seventh transistors T1, T2, T3, T4, T5, T6, and T7 may be P-type transistors and the other thereof may be N-type transistors. For example, the first, second, fifth, sixth, and seventh transistors T1, T2, T5, T6, and T7 may be P-type transistors, and the third and fourth transistors T3 and T4 may be N-type transistors.

A configuration of the pixel circuit PDC according to the present disclosure is not limited to an embodiment illustrated in FIG. 4. The pixel circuit PDC illustrated in FIG. 4 is merely an example and a configuration of the pixel circuit PDC may be modified and implemented. For example, all the first to seventh transistors T1, T2, T3, T4, T5, T6, and T7 may be P-type transistors or N-type transistors. Alternatively, the first, second, fifth, and sixth transistors T1, T2, T5, and T6 may be P-type transistors, and the third, fourth, and seventh transistors T3, T4, and T7 may be N-type transistors.

The j^{th} initialization scan line GILj, the j^{th} compensation scan line GCLj, the j^{th} write scan line GWLj, the j^{th} black scan line GBLj, and the j^{th} light emitting control line ECLj may transmit, to the pixel Pxij, a j^{th} initialization scan signal Gij, a j^{th} compensation scan signal GCj, a j^{th} write scan signal GWj, a j^{th} black scan signal GBj, and a j^{th} light emitting control signal Emj, respectively. The i^{th} data line Dli transmits the i^{th} data signal Di to the pixel Pxij. The i^{th} data signal Di may have a voltage level corresponding to an image signal input to the display device DD or various components thereof (see FIG. 1).

The first and second driving voltage lines VL1 and VL2 may transmit, to the pixel Pxij, a first driving voltage ELVDD and a second driving voltage ELVSS, respectively. Further, the first and second initialization voltage lines VL3 and VL4 may transmit, to the pixel Pxij, a first initialization voltage VINT and a second initialization voltage VAINT, respectively.

The first transistor T1 is connected between the first driving voltage line VL1 that receives the first driving voltage ELVDD and the light emitting element ED. The first transistor T1 includes a first electrode connected to the first driving voltage line VL1 via the fifth transistor T5, a second electrode connected to a pixel electrode (or referred to as an anode AE) of the light emitting element ED via the sixth transistor T6, and a third electrode (for example, a gate electrode) connected to one end (for example, a first node N1) of the first capacitor Cst. The first transistor T1 may receive the i^{th} data signal Di transmitted by the i data line DLi^{th} according to a switching operation of the second transistor T2 and supply a driving current to the light emitting element ED.

The second transistor T2 is connected between the data line DLi and the first electrode of the first transistor T1. The second transistor T2 includes a first electrode connected to the data line DLi, a second electrode connected to the first electrode of the first transistor T1, and a third electrode (for example, a gate electrode) connected to the j^{th} write scan line GWLj. The second transistor T2 may be turned on according to the write scan signal GWj transmitted through the j^{th} write scan line GWLj and may transmit the i^{th} data signal Di transmitted from the i^{th} data line DLi to the first electrode of the first transistor T1. One end of the second capacitor Cbst may be connected to the third electrode of the second transistor T2, and the other end of the second capacitor Cbst may be connected to the first node N1.

The third transistor T3 is connected between the second electrode of the first transistor T1 and the first node N1. The third transistor T3 includes a first electrode connected to the third electrode of the first transistor T1, a second electrode connected to the second electrode of the first transistor T1, and a third electrode (for example, a gate electrode) connected to the j^{th} compensation scan line GCLj. The third transistor T3 may be turned on according to the j^{th} compensation scan signal GCj transmitted through the j^{th} compensation scan line GCLj, may connect the third electrode of the first transistor T1 and the second electrode of the first transistor T1 to each other, and thus may diode-connect the first transistor T1. One end of the third capacitor Nbst may be connected to the third electrode of the third transistor T3, and the other end of the third capacitor Nbst may be connected to the first node N1.

The fourth transistor T4 is connected between the first initialization voltage line VL3 to which the first initialization voltage VINT is applied and the first node N1. The fourth transistor T4 includes a first electrode connected to the first initialization voltage line VL3 to which the first initialization voltage VINT is applied, a second electrode connected to the first node N1, and a third electrode (for example, a gate electrode) connected to the j^{th} initialization scan line GILj. The fourth transistor T4 is turned on according to the j^{th} initialization scan signal GIj transmitted through the j^{th} initialization scan line GILj. The turned-on fourth transistor T4 transmits the first initialization voltage VINT to the first node N1 and initializes a potential of the third electrode of the first transistor T1 (that is, a potential of the first node N1).

The fifth transistor T5 includes a first electrode connected to the first driving voltage line VL1, a second electrode connected to the first electrode of the first transistor T1, and a third electrode (for example, a gate electrode) connected to the j^{th} light emitting control line ECLj. The third transistor T6 includes a first electrode connected to the second electrode of the first transistor T1, a second electrode connected to the pixel electrode of the light emitting element ED, and a third electrode (for example, a gate electrode) connected to the j^{th} light emitting control line ECLj.

The fifth and sixth transistors T5 and T6 are simultaneously turned on according to the j^{th} light emitting control signal EMj transmitted through the j^{th} light emitting control line ECLj. The first driving voltage ELVDD applied through the turned-on fifth transistor T5 may be compensated for through the diode-connected first transistor T1 and may then be transmitted to the light emitting element ED through the sixth transistor T6.

The seventh transistor T7 includes a first electrode connected to the second initialization voltage line VL4 to which the second initialization voltage VAINT is applied, a second electrode connected to the second electrode of the sixth transistor T6, and a third electrode (for example, a gate electrode) connected to the j^{th} black scan line GBLj. The second initialization voltage VAINT may have a voltage level lower than or equal to the first initialization voltage VINT.

One end of the first capacitor Cst is connected to the third electrode of the first transistor T1, and the other end of the first capacitor Cst is connected to the first driving voltage line VL1. A cathode CE of the light emitting element ED may be connected to the second driving voltage line VL2 that transmits the second driving voltage ELVSS. The second driving voltage ELVSS may have a voltage level lower than the first driving voltage ELVDD.

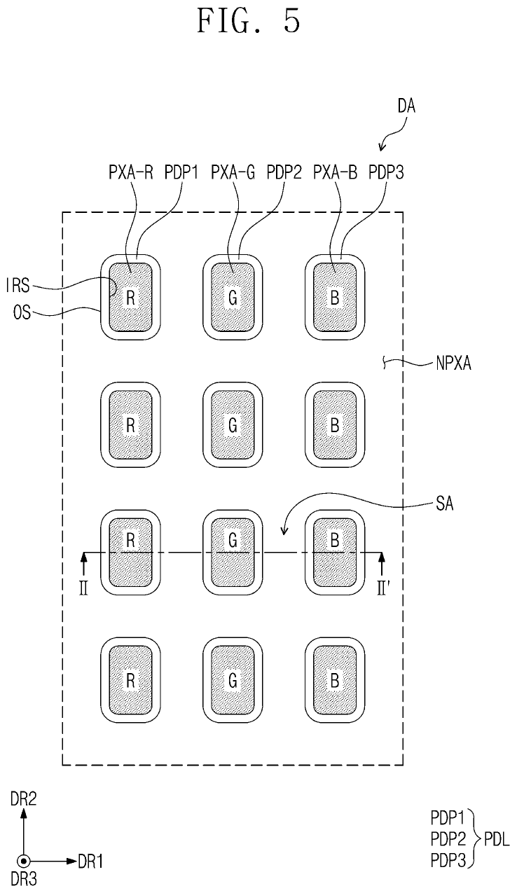

FIG. 5 is an enlarged plan view of a portion of the display area DA of the display panel DP (see FIG. 2) according to an embodiment of the present disclosure. FIG. 5 illustrates a plan view of the display module DM when viewed from the display surface IS (see FIG. 1B) of the display module DM (see FIG. 1B) and illustrates a light emitting area PXA provided in plural including a plurality of light emitting areas PXA-R, PXA-G, and PXA-B, and a pixel defining film PDL as a pixel defining layer.

Referring to FIG. 5, the display area DA may include the first to third light emitting areas PXA-R, PXA-G, and PXA-B, and a peripheral area NPXA which surrounds each of the first to third light emitting areas PXA-R, PXA-G, and PXA-B.

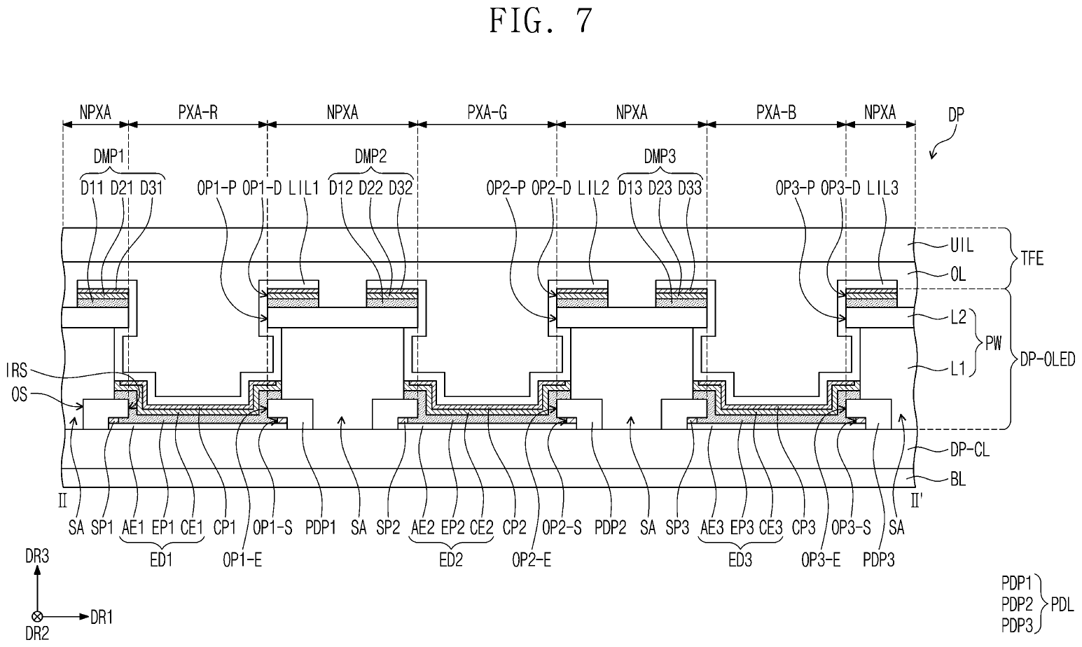

The first to third light emitting areas PXA-R, PXA-G, and PXA-B may be areas (e.g., planar areas) through which light provided from light emitting elements ED1, ED2, and ED3 of a light emitting element layer (see FIG. 7) is emitted. The first to third light emitting areas PXA-R, PXA-G, and PXA-B may be classified according to the color of the light emitted toward the outside of the display module DM (see FIG. 2). The first to third light emitting areas PXA-R, PXA-G, and PXA-B may provide first to third color lights having different colors, respectively. For example, the first color light may be red light, the second color light may be green light, and the third color light may be blue color. However, examples of the first to third color lights are not necessarily limited to the above example.

Each of the first to third light emitting areas PXA-R, PXA-G, and PXA-B may be defined as an area in which an upper surface of the anode is exposed by a light emitting opening, which will be described below. The peripheral area NPXA may set boundaries between the first to third light emitting areas PXA-R, PXA-G, and PXA-B and prevent color mixing between the first to third light emitting areas PXA-R, PXA-G, and PXA-B.

The planar shapes, the planar areas, the planar arrangements, and the like of the first to third light emitting areas PXA-R, PXA-G, and PXA-B of the display module DM (see FIG. 2) of the present disclosure may be variously designed according to the color of the emitted light or the size and configuration of the display module DM.

Each of the first to third light emitting areas PXA-R, PXA-G, and PXA-B may be provided in plural and may be repeatedly arranged in the display area DA in a specific arrangement form. For example, the first to third light emitting areas PXA-R, PXA-G, and PXA-B may be arranged spaced apart from each other along the first direction DR1 to constitute a “first group.” The “first group” may be provided as a plurality of “first groups” which are arranged along the second direction DR2.

FIG. 5 illustratively illustrates a form in which the first to third light emitting areas PXA-R, PXA-G, and PXA-B are arranged in one single direction, but the present disclosure is not limited thereto, and the first to third light emitting areas PXA-R, PXA-G, and PXA-B may be arranged in various forms. In an embodiment, the first to third light emitting areas PXA-R, PXA-G, and PXA-B may have a PENTILE™ arrangement form or have a stripe arrangement form or a Diamond Pixel™ arrangement form.

The first to third light emitting areas PXA-R, PXA-G, and PXA-B may have various shapes on a plane. FIG. 5 illustratively illustrates the first to third light emitting areas PXA-R, PXA-G, and PXA-B having a quadrangular shape on a plane, but the present disclosure is not limited thereto. For example, the first to third light emitting areas PXA-R, PXA-G, and PXA-B may have a polygonal shape, a circular shape, an elliptical shape, or the like, the first to third light emitting areas PXA-R, PXA-G, and PXA-B may have the same shape on a plane, or at least some of the first to third light emitting areas PXA-R, PXA-G, and PXA-B may have different shapes from each other.

FIG. 5 illustratively illustrates that the first to third light emitting areas PXA-R, PXA-G, and PXA-B have the same planar area, but the present disclosure is not limited thereto, and the first to third light emitting areas PXA-R, PXA-G, and PXA-B may be variously designed according to a design of the display module DM (see FIG. 2). For example, at least some of the first to third light emitting areas PXA-R, PXA-G, and PXA-B may have different areas on a plane. In an embodiment, an area of the first light emitting area PXA-R emitting red light may be greater than an area of the second light emitting area PXA-G emitting green light and may be smaller than an area of the third light emitting area PXA-B emitting blue light.

The pixel defining film PDL may be positioned on or corresponding to the peripheral area NPXA. The pixel defining film PDL may include a plurality of pixel defining patterns PDP1, PDP2, and PDP3 as solid material portions of the pixel defining film PDL which are spaced apart from each other. The plurality of pixel defining patterns PDP1, PDP2, and PDP3 may include the first pixel defining pattern PDP1, the second pixel defining pattern PDP2, and the third pixel defining pattern PDP3. Each of the plurality of pixel defining patterns PDP1, PDP2, and PDP3 may include an inner surface IRS and an outer surface OS which surrounds the inner surface IRS. That is, the pixel defining film PDL may include a side surface which defines the inner surface IRS and the outer surface OS.

When viewed on a plane, the first pixel defining pattern PDP1, the second pixel defining pattern PDP2, and the third pixel defining pattern PDP3 may surround the corresponding light emitting areas PXA-R, PXA-G, and PXA-B, respectively. For example, the first pixel defining pattern PDP1 may surround the first light emitting area PXA-R, the second pixel defining pattern PDP2 may surround the second light emitting area PXA-G, and the third pixel defining pattern PDP3 may surround the third light emitting area PXA-B.

Further, since the plurality of pixel defining patterns PDP1, PDP2, and PDP3 are formed or provided to respectively surround the first to third light emitting areas PXA-R, PXA-G, and PXA-B, the plurality of pixel defining patterns PDP1, PDP2, and PDP3 may be arranged along the first to third light emitting areas PXA-R, PXA-G, and PXA-B to be spaced apart from each other in the first direction DR1 and the second direction DR2. A separation space SA may be defined between the plurality of pixel defining patterns PDP1, PDP2, and PDP3. The separation space SA may be a minimum distance between the outer surface of adjacent pixel defining patterns, in a direction along the display area DA.

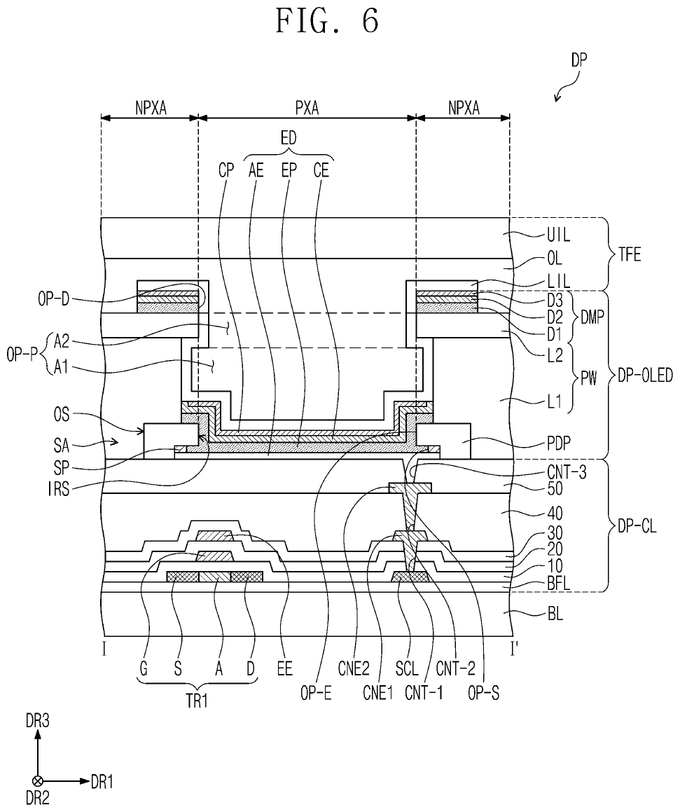

FIG. 6 is a cross-sectional view of the display panel DP along line I-I′ of FIG. 3. In description of FIG. 6, the description will be made with reference to FIG. 2, and descriptions for the same reference numerals will be omitted.

FIG. 6 is an enlarged view illustrating one light emitting area PXA in the display area DA (see FIG. 3), and the light emitting area PXA of FIG. 6 may corresponds to one of the first to third light emitting areas PXA-R, PXA-G, and PXA-B of FIG. 5.

Referring to FIG. 6, the display panel DP may include the base layer BL, the circuit element layer DP-CL, the display element layer DP-OLED, and the thin film encapsulation layer TFE.

The display panel DP may include a plurality of insulating layers, a plurality of semiconductor patterns, a plurality of conductive patterns, a plurality of signal lines, and the like. The insulating layer, the semiconductor layer, and the conductive layer are formed or provided by coating, deposition, or the like. Thereafter, the insulating layer, the semiconductor layer, and the conductive layer may be selectively patterned by photolithography and etching. In this manner, the semiconductor pattern, the conductive pattern, the signal line, and the like included in the circuit element layer DP-CL and the display element layer DP-OLED may be formed.

The circuit element layer DP-CL may be disposed on the base layer BL. The circuit element layer DP-CL may include a buffer layer BFL, a transistor TR1, a signal transmission area SCL as a signal transmission line or signal line, first to fifth insulating layers 10, 20, 30, 40, and 50, an electrode EE, and a connection electrode provided in plural including a plurality of connection electrodes CNE1 and CNE2. One or more of the above elements may be provided in plural within the display panel DP.

The buffer layer BFL may be disposed on the base layer BL. The buffer layer BFL may improve a coupling force between the base layer BL and the semiconductor pattern. The buffer layer BFL may include a silicon oxide layer and a silicon nitride layer. The silicon oxide layer and the silicon nitride layer may be alternately laminated.

The semiconductor pattern may be disposed on the buffer layer BFL. The semiconductor pattern may include polysilicon. However, the present disclosure is not limited thereto, and the semiconductor pattern may include amorphous silicon or metal oxide. FIG. 6 illustratively illustrates a portion of the semiconductor pattern, and the semiconductor patterns may be further arranged in the plurality of light emitting areas PXA-R, PXA-G, and PXA-B (see FIG. 5). The semiconductor pattern may be arranged in a specific rule across the plurality of light emitting areas PXA-R, PXA-G, and PXA-B.

The semiconductor pattern may have a different electrical property depending on whether or not a portion of the semiconductor pattern is doped. The semiconductor pattern may include a first area having a high doping concentration and a second area having a low doping concentration. The first area may be doped with an N-type dopant or a P-type dopant. A P-type transistor may include the first area doped with the P-type dopant.

Within the semiconductor pattern, a conductivity of the first area is greater than a conductivity of the second area, and the first area may substantially serve as an electrode or a signal line. The second area may correspond to an active area (or a channel) of a transistor substantially. In other words, a portion of the semiconductor pattern may be the active area of the transistor, another portion of the semiconductor pattern may be a source or a drain of the transistor, and still another portion of the semiconductor pattern may be a conductive area.

A source “S,” an active area “A,” and a drain “D” of the transistor TR1 may be formed from the semiconductor pattern. FIG. 6 illustrates a portion of the signal transmission area SCL formed from the semiconductor pattern. Although not separately illustrated, the signal transmission area SCL may be connected to the drain “D” of the transistor TR1 on a plane. That is, the source “S” the active area “A” the drain “D” and the signal transmission area SCL may be respective portions or patterns of a same semiconductor layer (or a same semiconductor material layer). As being in a same layer, elements may be formed or provided in a same process and/or include a same material as each other, elements may be respective portions of a same (material) layer, elements may be on a same layer by forming an interface with a same underlying or overlying layer, etc., without being limited thereto.

The first to fifth insulating layers 10, 20, 30, 40, and 50 may be arranged on the buffer layer BFL. The first to fifth insulating layers 10, 20, 30, 40, and 50 may be inorganic layers or organic layers.

The first insulating layer 10 may be disposed on the buffer layer BFL. The first insulating layer 10 may cover the source “S,” the active area “A,” and the drain “D” of the transistor TR1 disposed on the buffer layer BFL, and the signal transmission area SCL. A gate “G” of the transistor TR1 may be disposed on the first insulating layer 10. The second insulating layer 20 may be disposed on the first insulating layer 10 to cover the gate “G.” The electrode EE may be disposed on the second insulating layer 20. The third insulating layer 30 may be disposed on the second insulating layer 20 to cover the electrode EE.

The first connection electrode CNE1 may be disposed on the third insulating layer 30. The first connection electrode CNE1 may be connected to the signal transmission area SCL through a first contact hole CNT-1 passing through the first to third insulating layers 10, 20, and 30. The fourth insulating layer 40 may be disposed on the third insulating layer 30 to cover the first connection electrode CNE1. The fourth insulating layer 40 may be an organic layer.

The second connection electrode CNE2 may be disposed on the fourth insulating layer 40. The second connection electrode CNE2 may be connected to the first connection electrode CNE1 through a second contact hole CNT-2 passing through the fourth insulating layer 40. The fifth insulating layer 50 may be disposed on the fourth insulating layer 40 to cover the second connection electrode CNE2. The fifth insulating layer 50 may be an organic layer.

The display element layer DP-OLED may be disposed on the circuit element layer DP-CL. The display element layer DP-OLED may include the light emitting element ED, a sacrificial pattern SP, the pixel defining pattern PDP, a partition wall PW, and a dummy pattern DMP. One or more of the above elements may be provided in plural within the display panel DP.

The light emitting element ED may include an anode AE (or a first electrode), a light emitting pattern EP, and a cathode CE (or a second electrode). Each of the first to third light emitting elements ED1, ED2, and ED3, which will be described below, may include substantially the same configuration as that of the light emitting element ED of FIG. 6. Descriptions of the anode AE, the light emitting pattern EP, and the cathode CE may be applied to all the anode AE, the light emitting pattern EP, and the cathode CE of each of the first to third light emitting elements ED1, ED2, and ED3, which will be described below.

The anode AE may be disposed on the fifth insulating layer 50 of the circuit element layer DP-CL. The anode AE may be a transmissive electrode, a semi-transmissive electrode, or a reflective electrode. The anode AE may be conductive. For example, the anode AE may be formed of or include various materials such as a metal, a transparent conductive oxide (TCO), and a conductive polymer material as long as the materials may be conductive. For example, the anode AE that is metal may include gold (Au), silver (Ag), aluminum (Al), magnesium (Mg), lithium (Li), molybdenum (Mo), copper (Cu), or alloys thereof. The anode AE that is a transparent conductive oxide may include indium tin oxide (ITO), indium zinc oxide (IZO), zinc oxide (ZnO), indium oxide (InO), indium Gallium oxide (IGO), or aluminum zinc oxide (AZO).

The anode AE may be connected to the second connection electrode CNE2 through a connection contact hole CNT-3 defined through the fifth insulating layer 50. Thus, the anode AE may be electrically connected to the signal transmission area SCL through the first and second connection electrodes CNE1 and CNE2 and thus electrically connected to the corresponding circuit element. The anode AE may include a single-layer structure or a multi-layer structure.

The sacrificial pattern SP may be disposed between the anode AE and the pixel defining film PDL. Specifically, the sacrificial pattern SP as a solid material portion of a sacrificial layer may be between the anode AE and the pixel definition pattern PDP as a solid material portion of the pixel defining film PDL. A sacrificial opening OP-S exposing a portion of an upper surface of the anode AE to outside the sacrificial layer, may be defined in the sacrificial pattern SP. The sacrificial opening OP-S may overlap a light emitting opening OP-E, which will be described below.

The pixel defining pattern PDP may be disposed on the fifth insulating layer 50 of the circuit element layer DP-CL. The light emitting opening OP-E may be defined by the pixel defining pattern PDP. The light emitting opening OP-E may correspond to the exposed portion of the anode AE, and the pixel defining pattern PDP may expose at least a portion of the anode AE to outside the pixel defining film PDL, through the light emitting opening OP-E. The pixel defining pattern PDP may be provided as a plurality of pixel defining patterns PDP, and the separation space SA may be defined between facing outer surfaces of the plurality of pixel defining patterns PDP.

At the separation space SA, the fifth insulating layer 50 is exposed to outside the pixel defining film PDL. Particularly, an upper surface of the fifth insulating layer 50 which is closest to the display element layer DP-OLED, is uncovered by the patterns of the pixel defining film PDL.

According to the present disclosure, since the pixel defining pattern PDP does not cover portions of the front (or upper) surface of the fifth insulating layer 50, a gas generated in the fifth insulating layer 50 is not blocked by the pixel defining pattern PDP and may be easily discharged out of the firth insulating layer 50. Thus, as the gas generated during a process of providing and/or driving of the display device DD is easily discharged, a lifetime of the pixel PX may increase.

Further, the light emitting opening OP-E may correspond to the sacrificial opening OP-S of the sacrificial pattern SP. As corresponding, the two openings may overlap or be aligned with each other. According to an embodiment, the exposed portion of the upper surface of the anode AE may be spaced apart from the pixel defining film PDL in a cross section and in a direction along the circuit element layer DP-CL, by the sacrificial pattern SP interposed therebetween. Accordingly, damage to the anode AE may be protected in a process of forming the light emitting opening OP-E in the pixel defining film PDL.

On a plane, an area of the light emitting opening OP-E may be smaller than an area of the sacrificial opening OP-S. The area may refer to a total planar area of a respective opening which is defined by dimensions along the plane defined by the first direction DR1 crossing the second direction DR2. Each of the patterns of the pixel defining film PDL and the patterns of the sacrificial layer, may have an inner surface which is closest to a center of the anode AE, in the plan view. Referring to FIG. 6 for example, the inner surface IRS of the pixel defining film PDL which defines the light emitting opening OP-E may be closer to a center of the anode AE than the inner surface of the sacrificial pattern SP which defines the sacrificial opening OP-S. That is, the pixel definition pattern PDP may extend further than the inner surface of the sacrificial pattern SP in a direction toward the center of the anode AE However, the present disclosure is not limited thereto, and the inner surface of the sacrificial pattern SP defining the sacrificial opening OP-S may be substantially aligned with the inner surface of the pixel defining film PDL defining the corresponding light emitting opening OP-E, such that the two inner surfaces are coplanar with each other. In this case, the light emitting area PXA may be regarded as a planar area of the anode AE which is exposed to outside the corresponding sacrificial opening OP-S.

The pixel defining pattern PDP may include an inorganic material and include an insulating material. For example, the pixel defining pattern PDP may include a silicon nitride (SiNx). The pixel defining pattern PDP may be disposed between the anode AE and the partition wall PW and block electrical connection between the anode AE and the partition wall PW. As blocking an electrical connection, the pixel defining pattern PDP may effectively insulate the anode AE and the partition wall PW from each other.

The partition wall PW may be disposed on the fifth insulating layer 50 and the pixel defining pattern PDP. At least a portion of the partition wall PW may cover a portion of the pixel defining pattern PDP and may fill the separation space SA defined between the plurality of pixel defining patterns PDP. A partition wall opening OP-P may be defined in the partition wall PW. The partition wall opening OP-P may correspond to the light emitting opening OP-E and expose at least a portion of the anode AE to outside the partition wall layer. That is, the partition wall opening OP-P may overlap the anode AE.

The partition wall PW may have an undercut shape in a cross section. The partition wall PW may include a plurality of layers that are sequentially laminated, and at least one layer of the plurality of layers may be recessed as compared to other layers, with respect to the center of the anode AE. Accordingly, the partition wall PW may include a tip or overhang portion within the undercut or recessed structure.

The partition wall PW may include a first partition wall layer L1 and a second partition wall layer L2. A portion of the first partition wall layer L1 may be disposed on the pixel defining pattern PDP, and the second partition wall layer L2 may be disposed on the first partition wall layer L1. The conductivity of the first partition wall layer L1 may be greater than the conductivity of the second partition wall layer L2. The first partition wall layer L1 may be relatively recessed as compared to the second partition wall layer L2 with respect to a center of the light emitting area PXA. That is, the first partition wall layer L1 may be formed by being undercut with respect to the second partition wall layer L2.

The partition wall opening OP-P defined in the partition wall PW may include a first area A1 representing a first volume and a second area A2 representing a second volume. The first partition wall layer L1 may include a first inner surface defining the first area A1 of the partition wall opening OP-P, and the second partition wall layer L2 may include a second inner surface defining the second area A2. The first inner surface may be relatively recessed inward as compared to the second inner surface.

FIG. 6 illustratively illustrates a state in which each of the first inner surface and the second inner surface is perpendicular to an upper surface of the pixel defining pattern PDP, but the present disclosure is not limited thereto. For example, the partition wall PW may have a tapered shape or a reverse tapered shape. That is, one or more of the inner surfaces may be inclined with respect to the upper surface of the pixel defining pattern PDP.

The first partition wall layer L1 may include a conductive material. The conductive material may include a metal, a transparent conductive oxide (TCO), or a combination thereof. For example, the metal includes gold (Au), silver (Ag), aluminum (Al), magnesium (Mg), lithium (Li), molybdenum (Mo), titanium (Ti), copper (Cu), or alloys thereof. The transparent conductive oxide may include indium tin oxide (ITO), indium zinc oxide (IZO), zinc oxide, indium oxide, indium gallium oxide, indium gallium zinc oxide (IGZO), or aluminum zinc oxide.

The second partition wall layer L2 may include a metal or a non-metal. For example, the metal includes gold (Au), silver (Ag), aluminum (Al), magnesium (Mg), lithium (Li), molybdenum (Mo), titanium (Ti), copper (Cu), or alloys thereof. The non-metal may include silicon (Si), silicon oxide (SiOx), silicon nitride (SiNx), silicon oxynitride (SiON), metal oxide, metal nitride, or combinations thereof, where the metal oxide may include transparent conductive oxide (TCO).

According to an embodiment, the partition wall PW may further include layers arranged below the first partition wall layer L1, above the second partition wall layer L2, or between the first partition wall layer L1 and the second partition wall layer L2. In this case, the additionally arranged layers may include at least one of the conductive material and the inorganic material.

The light emitting pattern EP may be disposed on the anode AE. The light emitting pattern EP may include a light emitting layer including a light emitting material. The light emitting pattern EP may further include a hole injection layer (HIL) and a hole transport layer (HTL) arranged between the anode AE and the light emitting layer and may further include an electron transport layer (ETL) and an electron injection layer (EIL) arranged on the light emitting layer. The light emitting pattern EP may be referred to as an “organic layer” or an “intermediate layer.”

In a process of providing the display element layer DP-OLED, the light emitting pattern EP may be effectively patterned from a light emitting material layer by the tip portion of the partition wall PW. The light emitting pattern EP may be disposed inside each of the sacrificial opening OP-S, the light emitting opening OP-E, and the partition wall opening OP-P which together may define an opening. The light emitting pattern EP may extend from the collective opening, along the inner surfacer IRS of the pixel definition pattern PDP, and along an upper surface of the pixel definition pattern PDP to cover a portion of the upper surface of the pixel defining film PDL exposed outside of the partition wall opening OP-P.

The cathode CE may be disposed on the light emitting pattern EP. In a process of providing the display element layer DP-OLED, the cathode CE may be effectively patterned by the tip portion of the partition wall PW. The cathode CE may be in contact with the first inner surface of the first partition wall layer L1 defining the first area A1. The cathode CE may be conductive. For example, the cathode CE may be formed of various materials such as a metal, a transparent conductive oxide (TCO), and a conductive polymer material as long as the materials may be conductive.

The partition wall PW may receive the second driving voltage ELVSS (see FIG. 4), and accordingly, the cathode CE may be electrically connected to the partition wall PW to receive the second driving voltage ELVSS (see FIG. 4).

According to an embodiment of the present disclosure, the display panel DP may further include a capping pattern CP. The capping pattern CP may be disposed inside the partition wall opening OP-P and disposed on the cathode CE. Similar to that described above, the capping pattern CP may be effectively patterned by using the tip portion of the partition wall PW.

FIG. 6 illustratively illustrates a state in which the capping pattern CP is not in contact with the first inner surface of the first partition wall layer L1, but the present disclosure is not limited thereto. For example, the capping pattern CP may extend from the respective opening to be formed in contact with the first inner surface of the first partition wall layer L1. According to an embodiment of the present disclosure, the capping pattern CP may be omitted. As being in contact, elements may form an interface therebetween, without being limited thereto.

The dummy pattern DMP may be provided in plural including a plurality of dummy patterns DMP disposed on the partition wall PW. The dummy patterns DMP may include a first dummy pattern D1 in a first dummy pattern layer, a second dummy pattern D2 in a second dummy pattern layer, and a third dummy pattern D3 in a third dummy pattern layer. The firsts to third dummy patterns D1, D2, and D3 may be sequentially laminated on an upper surface of the second partition wall layer L2 of the partition wall PW, in the third direction DR3.

The first dummy pattern D1 may include an organic material. For example, the first dummy pattern D1 may include the same material as that of the light emitting pattern EP. The first dummy pattern D1 together with the light emitting pattern EP may be simultaneously formed from a same material layer, through one process. The first dummy pattern D1 may be formed separately from the light emitting pattern EP by the undercut shape of the partition wall PW. That is, a light emitting material layer may be disconnected at the partition wall opening OP-P, to define the respective patterns of the first dummy pattern D1 and the light emitting pattern EP.

The second dummy pattern D2 may include a conductive material. For example, the second dummy pattern D2 may include the same material as that of the cathode CE. The second dummy pattern D2 together with the cathode CE may be simultaneously formed through one process. The second dummy pattern D2 may be formed separately from the cathode CE by the undercut shape of the partition wall PW.

The third dummy pattern D3 may include the same material as that of the capping pattern CP. The third dummy pattern D3 may be simultaneously formed through one process together with the capping pattern CP and formed separately from the capping pattern CP by the undercut shape of the partition wall PW.

A dummy opening OP-D may be defined in the dummy patterns DMP. The dummy opening OP-D may correspond to the light emitting opening OP-E. On a plane, each of the first to third dummy patterns D1, D2, and D3 may have a closed-line shape or a closed-loop shape surrounding the light emitting area PXA.

FIG. 6 illustratively illustrates a state in which inner surfaces of the first to third dummy patterns D1, D2, and D3 are aligned with the second inner surface of the second partition wall layer L2 (e.g., coplanar with each other), but the present disclosure is not limited thereto. In an embodiment, the first to third dummy patterns D1, D2, and D3 may extend along the second inner surface to cover the second inner surface of the second partition wall layer L2.

The thin film encapsulation layer TFE may be disposed on the display element layer DP-OLED. The thin film encapsulation layer TFE may include a lower encapsulation inorganic pattern LIL as a lower inorganic layer, an encapsulation organic film OL as an organic layer, and an upper encapsulation inorganic film UIL as an upper inorganic layer.

The lower encapsulation inorganic pattern LIL may correspond to and extend into the light emitting opening OP-E. The lower encapsulation inorganic pattern LIL may cover the light emitting element ED and the dummy patterns DMP, and a portion of the lower encapsulation inorganic pattern LIL may be disposed along a partition wall inner surface to be inside the partition wall opening OP-P. According to an embodiment, the lower encapsulation inorganic pattern LIL may be in contact with the first inner surface of the first partition wall layer L1.

The encapsulation organic film OL may cover the lower encapsulation inorganic pattern LIL and provide a flat upper surface. The upper encapsulation inorganic film UIL may be disposed on the encapsulation organic film OL.

The lower encapsulation inorganic pattern LIL and the upper encapsulation inorganic film UIL may protect the display element layer DP-OLED from moisture/oxygen, and the encapsulation organic film OL may protect the display element layer DP-OLED from foreign substances such as dust particles.

FIG. 7 is a cross-sectional view of the display panel DP along line II-II′of FIG. 5. FIG. 7 is an enlarged cross-sectional view of one first light emitting area PXA-R, one second light emitting area PXA-G, and one third light emitting area PXA-B, and the description of the one light emitting area PXA of FIG. 6 may be equally and repeatedly applied to the first to third light emitting areas PXA-R, PXA-G, and PXA-B. While FIGS. 6 and 7 are views in the second direction DR2, it will be understood that the structures in these views may be equally applied to features for a view in the first direction DR1.

Referring to FIG. 7, the display panel DP according to an embodiment may include the base layer BL, the circuit element layer DP-CL, the display element layer DP-OLED, and the thin film encapsulation layer TFE. The display element layer DP-OLED may include the light emitting elements ED1, ED2, and ED3, sacrificial patterns SP1, SP2, and SP3, the pixel defining film PDL, the partition wall PW, and the dummy patterns DMP.

The light emitting elements ED1, ED2, and ED3 may include the first light emitting element ED1, the second light emitting element ED2, and the third light emitting element ED3. The first light emitting element ED1 may include a first anode AE1, a first light emitting pattern EP1, and a first cathode CE1. The second light emitting element ED2 may include a second anode AE2, a second light emitting pattern EP2, and a second cathode CE2. The third light emitting element ED3 may include a third anode AE3, a third light emitting pattern EP3, and a third cathode CE3. The first to third anodes AE1, AE2, and AE3 may be provided as a plurality of patterns. In an embodiment, the first light emitting pattern EP1 may provide red light, the second light emitting pattern EP2 may provide green light, and the third light emitting pattern EP3 may provide blue light.

The pixel defining film PDL may include the first to third pixel defining patterns PDP1, PDP2, and PDP3. The first to third pixel defining patterns PDP1, PDP2, and PDP3 may be arranged spaced apart from each other in a direction along the circuit element layer DP-CL, and the separation space SA may be respectively defined between the first to third pixel defining patterns PDP1, PDP2, and PDP3 spaced apart from each other.

According to the present disclosure, the pixel defining film PDL includes the first to third pixel defining patterns PDP1, PDP2, and PDP3, which are spaced apart from each other, and thus the pixel defining film PDL may not cover a front surface of the fifth insulating layer 50 (see FIG. 6) of the circuit element layer DP-CL. That is, a portion of the upper surface of the fifth insulating layer 50 which is at the separation space SA and includes an organic material, may be exposed outside of the pixel defining film PDL. The gas generated in the fifth insulating layer 50 is not blocked by the pixel defining film PDL and may be easily discharged at the exposed portion of the fifth insulating layer 50. Thus, as the gas generated during a process is easily discharged, a lifetime of the pixel PX may increase.

First to third light emitting openings OP1-E, OP2-E, and OP3-E may be defined in or by the first to third pixel defining patterns PDP1, PDP2, and PDP3. The first light emitting opening OP1-E may expose at least a portion of the first anode AE1. The first light emitting area PXA-R may be defined as an area exposed by the first light emitting opening OP1-E among an upper surface of the first anode AE1. The second light emitting opening OP2-E may expose at least a portion of the second anode AE2. The second light emitting area PXA-G may be defined as an area exposed by the second light emitting opening OP2-E among an upper surface of the second anode AE2. The third light emitting opening OP3-E may expose at least a portion of the third anode AE3. The third light emitting area PXA-B may be defined as an area exposed by the third light emitting opening OP3-E among an upper surface of the third anode AE3.

Referring to FIGS. 5 and 7, one pixel defining pattern PDP1, PDP2, or PDP3 among the plurality of pixel defining patterns PDP1, PDP2, and PDP3 may surround a respective anode among the anodes AE1, AE2, or AE3. For example, the first pixel defining pattern PDP1 may surround the first anode AE1, the second pixel defining pattern PDP2 may surround the second anode AE2, and the third pixel defining pattern PDP3 may surround the third anode AE3.

That is, when viewed on a plane, the one pixel defining pattern PDP1, PDP2, or PDP3 among the plurality of pixel defining patterns PDP1, PDP2, and PDP3 may have a closed curve shape surrounding the anode (AE1, AE2, or AE3). For example, when viewed on a plane, the first to third pixel defining patterns PDP1, PDP2, and PDP3 may have closed curve shapes surrounding the first to third anodes AE1, AE2, and AE3, respectively.

The inner surface IRS of each of the plurality of pixel defining patterns PDP1, PDP2, and PDP3 may overlap the anodes AE1, AE2, and AE3, and the outer surface OS of each of the plurality of pixel defining patterns PDP1, PDP2, and PDP3 may not overlap the anodes AE1, AE2, and AE3.

Referring back to FIG. 7, the sacrificial patterns SP1, SP2, and SP3 may include the first sacrificial pattern SP1, the second sacrificial pattern SP2, and the third sacrificial pattern SP3. The first to third sacrificial patterns SP1, SP2, and SP3 may be arranged on upper surfaces of the first to third anodes AE1, AE2, and AE3, respectively. First to third sacrificial openings OP1-S, OP2-S, and OP3-S corresponding to the first to third light emitting openings OP1-E, OP2-E, and OP3-E may be defined in the first to third sacrificial patterns SP1, SP2, and SP3, respectively.

At least a portion of the partition wall PW may cover portions of the plurality of pixel defining patterns PDP1, PDP2, and PDP3 and may fill the separation space SA defined between the plurality of pixel defining patterns PDP1, PDP2, and PDP3.

First to third partition wall openings OP1-P, OP2-P, and OP3-P respectively corresponding to the first to third light emitting openings OP1-E, OP2-E, and OP3-E may be defined in the partition wall PW. Each of the first to third partition wall openings OP1-P, OP2-P, and OP3-P may include the first area A1 (see FIG. 6) and the second area A2 (see FIG. 6) described in FIG. 6.

The first light emitting pattern EP1 and the first cathode CE1 may be arranged in the first partition wall opening OP1-P, the second light emitting pattern EP2 and the second cathode CE2 may be arranged in the second partition wall opening OP2-P, and the third light emitting pattern EP3 and the third cathode CE3 may be arranged in the third partition wall opening OP3-P. The first to third cathodes CE1, CE2, and CE3 may be in contact with the first inner surfaces of the first partition wall layer L1.

In an embodiment, the first to third cathodes CE1, CE2, and CE3 may be physically separated by the second partition wall layer L2 forming the tip portion, may be thus formed inside the light emitting openings OP1-E, OP2-E, and OP3-E, may be electrically connected to each other while in contact with the first partition wall layer L1, and may thus receive a common voltage. The first partition wall layer L1 has relatively higher electrical conductivity than that of the second partition wall layer L2, so that contact resistance with the first to third cathodes CE1, CE2, and CE3 may be reduced. Accordingly, a common cathode voltage may be uniformly provided to the light emitting areas PXA-R, PXA-G, and PXA-B.

According to the present disclosure, the plurality of first light emitting patterns EP1 may be patterned and deposited in units of pixels PX by the tip portion defined in the partition wall PW. That is, a material layer for forming the first light emitting patterns EP1 may be commonly formed using an open mask, but may be easily divided in units of respective pixels PX by the tip of the partition wall PW. In an embodiment, the material layer for forming respective light emitting patterns may be divided solely by providing the material layer on the partition wall PW and the tip portions thereof.

On the other hand, unlike the present disclosure, when the first light emitting patterns EP1 are patterned using a fine metal mask (FMM), a support spacer protruding from the conventional partition wall to support the fine metal mask should be provided. Further, since the fine metal mask is spaced apart from a base surface, on which the patterning is performed, by a height of the conventional partition wall and the spacer, implementation in a high resolution may be limited. Further, as the fine metal mask is in contact with the spacer, after the patterning process for the first light emitting pattern EP1, foreign substances may remain on the spacer, and the spacer may be damaged due to stamping of the mask. Accordingly, a defective conventional display panel may be formed.

According to an embodiment, the partition wall PW is included so that physical separation between the light emitting elements ED1, ED2, and ED3 may be easily performed. Accordingly, current leakage or driving errors between the adjacent light emitting areas PXA-R, PXA-G, and PXA-B may be prevented, and independent driving for each of the light emitting elements ED1, ED2, and ED3 may be performed.

In particular, since the plurality of first light emitting patterns EP1 are patterned without a mask in contact with an inner component inside the display area DA (see FIG. 1B), a defect rate is reduced, and thus the display panel DP having improved process reliability may be provided. As the patterning may be performed even when the separate support spacer protruding from the partition wall PW is not provided, areas of the light emitting areas PXA-R, PXA-G, and PXA-B may be miniaturized, and thus the display panel DP that easily implements a high resolution may be provided.

Further, in manufacturing a large-area display panel DP, the display panel DP may be provided in which process cost may be reduced as production of a large-area mask is omitted, and process reliability may be improved as the display panel DP is not affected by defects that may occur in the large-area mask.

The capping patterns CP1, CP2, and CP3 may include the first capping pattern CP1, the second capping pattern CP2, and the third capping pattern CP3. The first to third capping patterns CP1, CP2, and CP3 may be arranged on the first to third cathodes CE1, CE2, and CE3 and arranged inside the first to third partition wall openings OP1-P, OP2-P, and OP3-P, respectively.

Referring to FIGS. 6 and 7, the dummy patterns DMP may include a plurality of first dummy patterns DMP1, a plurality of second dummy patterns DMP2, and a plurality of third dummy patterns DMP3.

The first dummy patterns DMP1 may include a (1-1)^{th} dummy pattern D11, a (2-1)^{th} dummy pattern D21, and a (3-1)^{th} dummy pattern D31 surrounding the first light emitting area PXA-R on a plane. The (1-1)^{th} dummy pattern D11, the (2-1)^{th} dummy pattern D21, and the (3-1)^{th} dummy pattern D31 may be sequentially arranged in the third direction DR3.

The second dummy patterns DMP2 may include a (1-2)^{th} dummy pattern D12, a (2-2)^{th} dummy pattern D22, and a (3-2)^{th} dummy pattern D32 surrounding the second light emitting area PXA-G on a plane. The (1-2)^{th} dummy pattern D12, the (2-2)^{th} dummy pattern D22, and the (3-2)^{th} dummy pattern D32 may be sequentially arranged in the third direction DR3.

The third dummy patterns DMP3 may include a (1-3)^{th} dummy pattern D13, a (2-3)^{th} dummy pattern D23, and a (3-3)^{th} dummy pattern D33 surrounding the third light emitting area PXA-B on a plane. The (1-3)^{th} dummy pattern D13, the (2-3)^{th} dummy pattern D23, and the (3-3)^{th} dummy pattern D33 may be sequentially arranged in the third direction DR3.

The (1-1)^{th} to (1-3)^{th} dummy patterns D11, D12, and D13 may include the same material as that of the first to third light emitting patterns EP1, EP2, and EP3, and may be formed through the same process as that of the first to third light emitting patterns EP1, EP2, and EP3. The (2-1)^{th} to (2-3)^{th} dummy patterns D21, D22, and D23 may include the same material as that of the first to third cathodes CE1, CE2, and CE3, and may be formed through the same process as that of the first to third cathodes CE1, CE2, and CE3. The (3-1)^{th} to (3-3)^{th} dummy patterns D31, D32, and D33 may include the same material as that of the first to third capping patterns CP1, CP2, and CP3, and may be formed through the same process as that of the first to third capping patterns CP1, CP2, and CP3.

First to third dummy openings OP1-D, OP2-D, and OP3-D respectively corresponding to the first to third light emitting openings OP1-E, OP2-E, and OP3-E may be defined in the dummy patterns DMP. The first dummy opening OP1-D may be defined by inner surfaces of the (1-1)^{th}, (2-1)^{th}, and (3-1)^{th} dummy patterns D11, D21, and D31, the second dummy opening OP2-D may be defined by inner surfaces of the (1-2)^{th} , (2-2)^{th} , and (3-2)^{th} dummy patterns D12, D22, and D32, and the third dummy opening OP3-D may be defined by inner surfaces of the (1-3)^{th}, (2-3)^{th}, and (3-3)^{th} dummy patterns D13, D23, and D33.

The thin film encapsulation layer TFE may include lower encapsulation inorganic patterns LIL1, LIL2, and LIL3, the encapsulation organic film OL, and the upper encapsulation inorganic film UIL. In an embodiment, the lower encapsulation inorganic patterns LIL1, LIL2, and LIL3 may include the first lower encapsulation inorganic pattern LIL1, the second lower encapsulation inorganic pattern LIL2, and the third lower encapsulation inorganic pattern LIL3. The first to third lower encapsulation inorganic patterns LIL1, LIL2, and LIL3 may correspond to the first to third light emitting openings OP1-E, OP2-E, and OP3-E, respectively.

The first lower encapsulation inorganic pattern LIL1 may cover the first light emitting element ED1 and the (1-1)^{th}, (2-1)^{th}, and (3-1)^{th} dummy patterns D11, D21, and D31, and a portion of the first lower encapsulation inorganic pattern LIL1 may be disposed inside the first partition wall opening OP1-P. The second lower encapsulation inorganic pattern LIL2 may cover the second light emitting element ED2 and the (1-2)^{th}, (2-2)^{th}, and (3-2)^{th} dummy patterns D12, D22, and D32, and a portion of the second lower encapsulation inorganic pattern LIL2 may be disposed inside the second partition wall opening OP2-P. The third lower encapsulation inorganic pattern LIL3 may cover the third light emitting element ED3 and the (1-3)^{th}, (2-3)^{th}, and (3-3)^{th} dummy patterns D13, D23, and D33, and a portion of the third lower encapsulation inorganic pattern LIL3 may be disposed inside the third partition wall opening OP3-P. The first to third lower encapsulation inorganic patterns LIL1, LIL2, and LIL3 may be provided in the form of patterns spaced apart from each other.

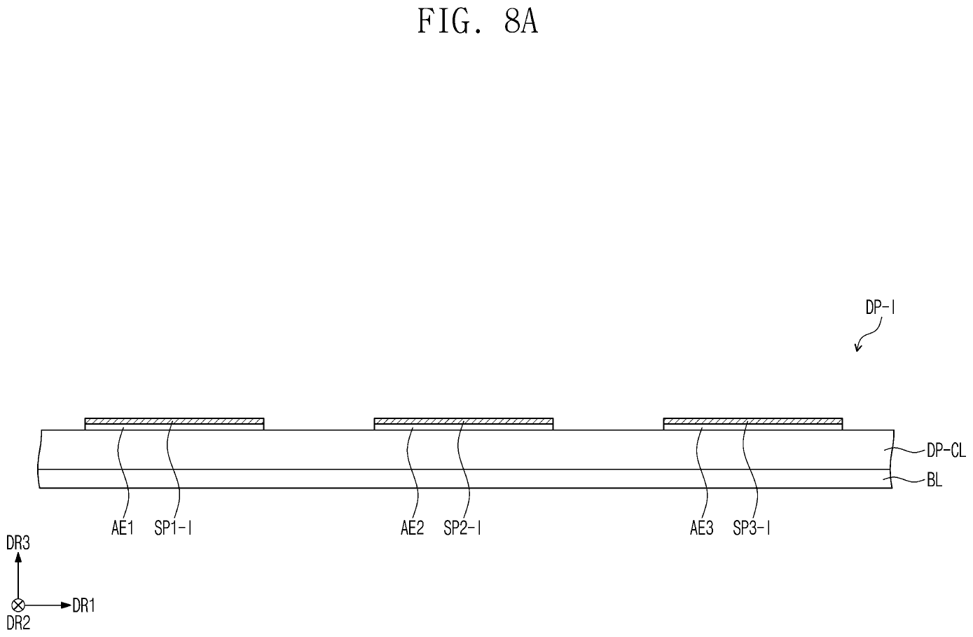

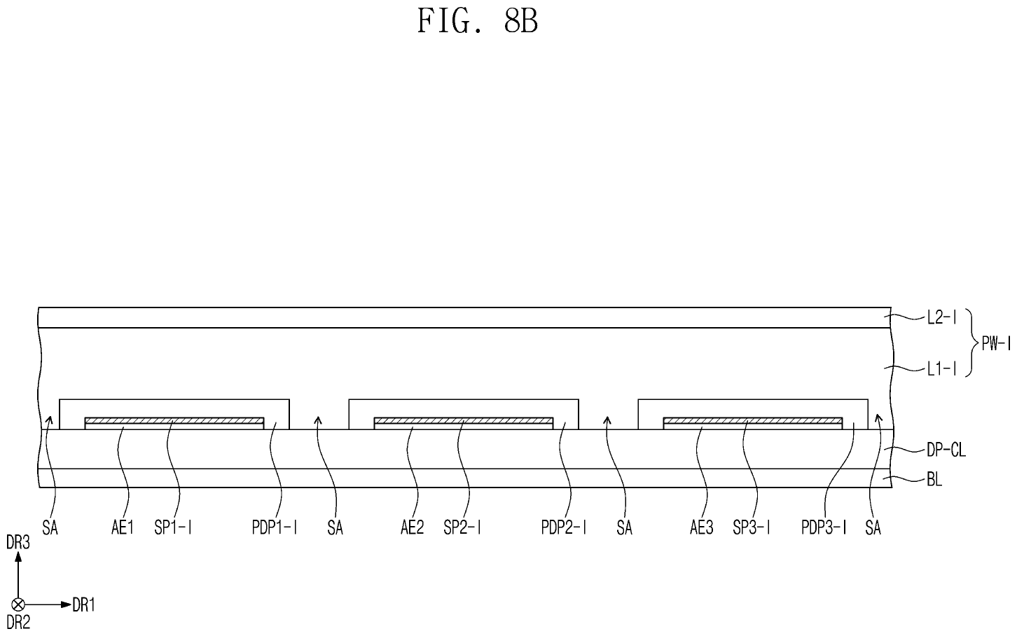

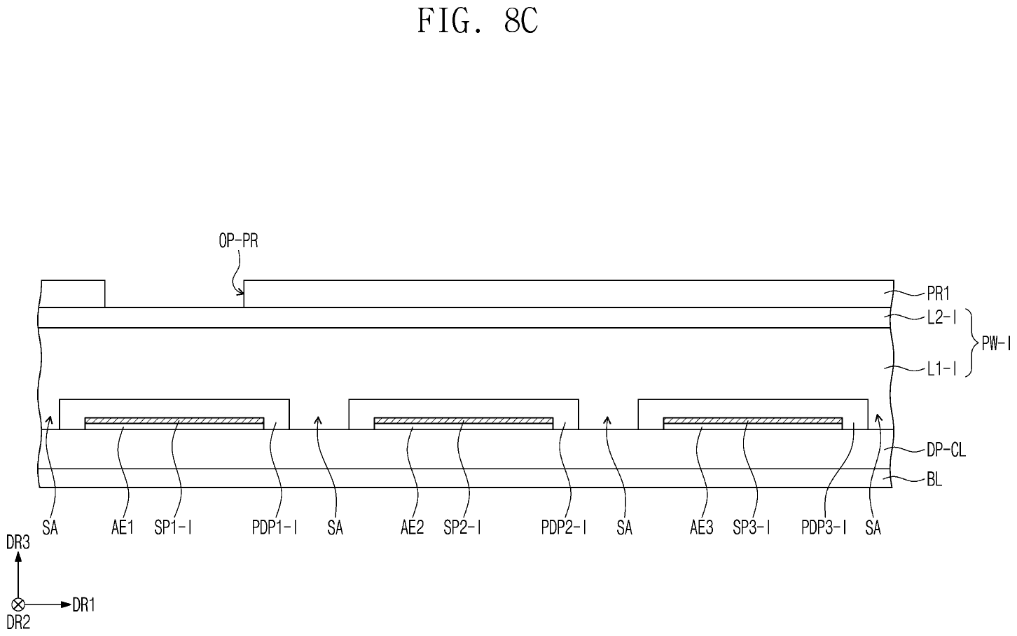

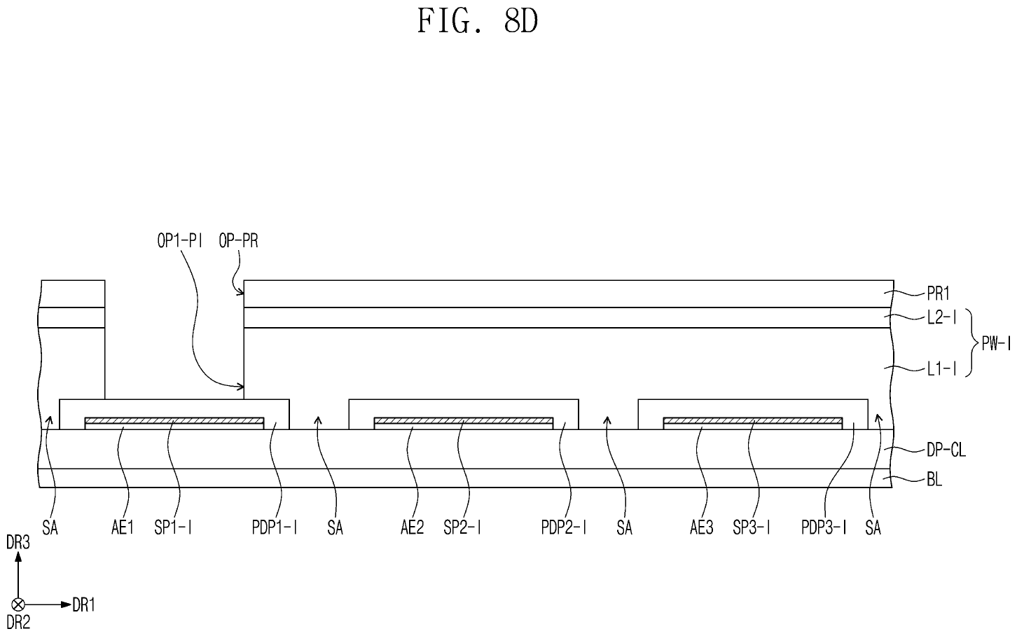

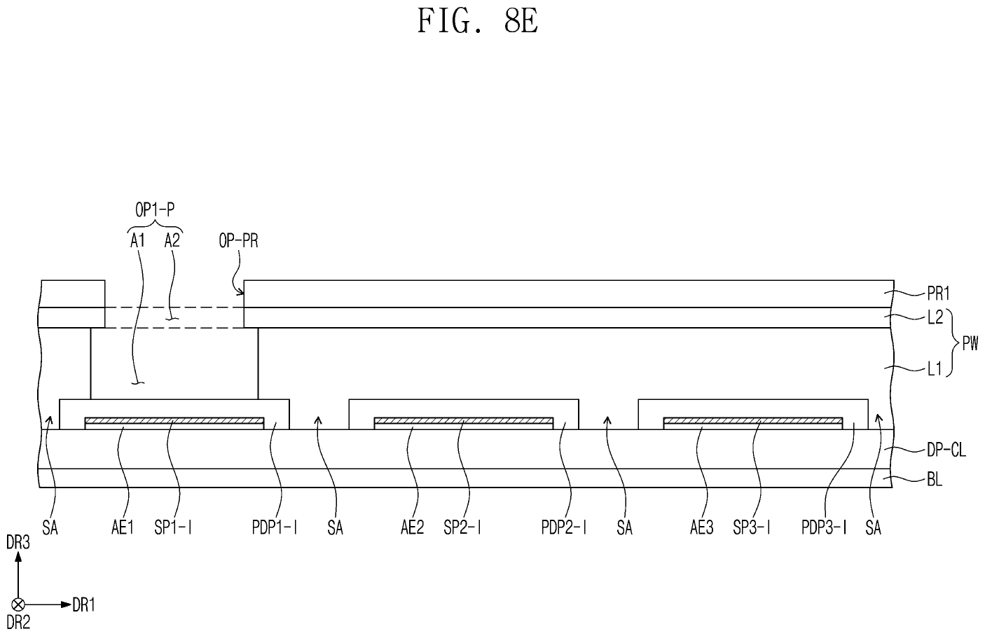

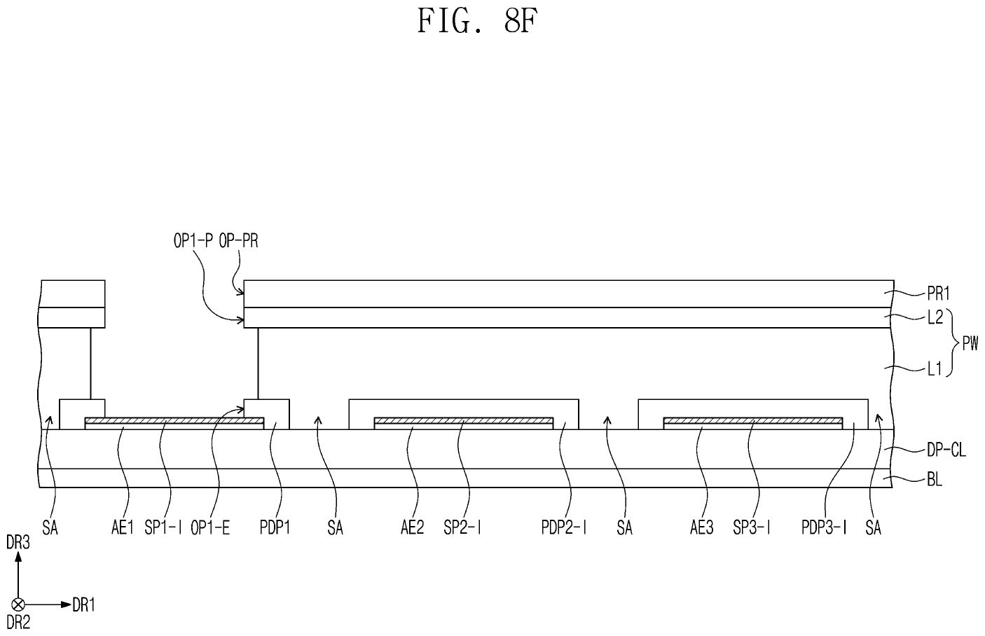

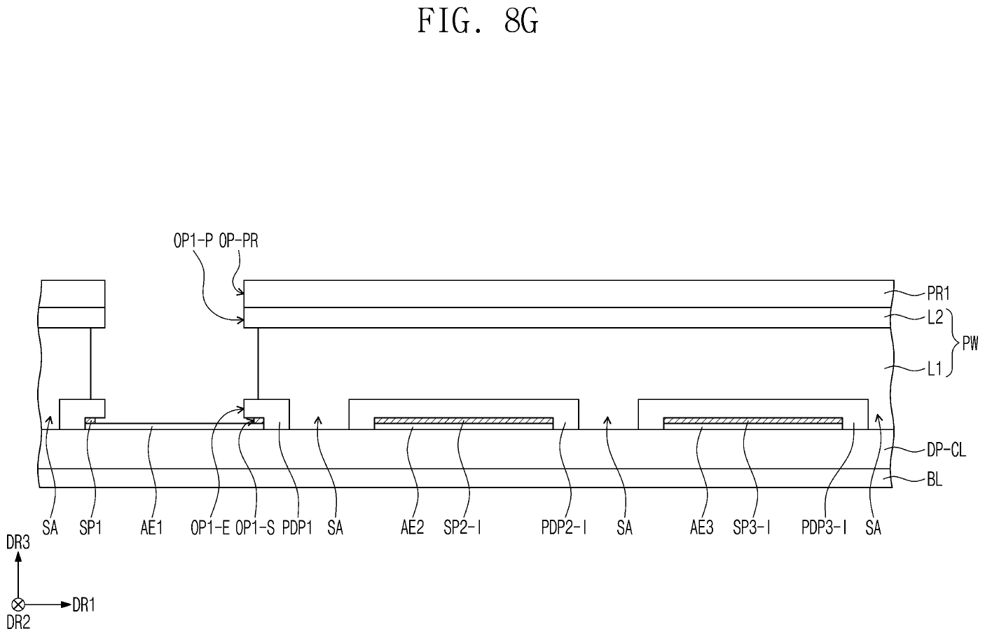

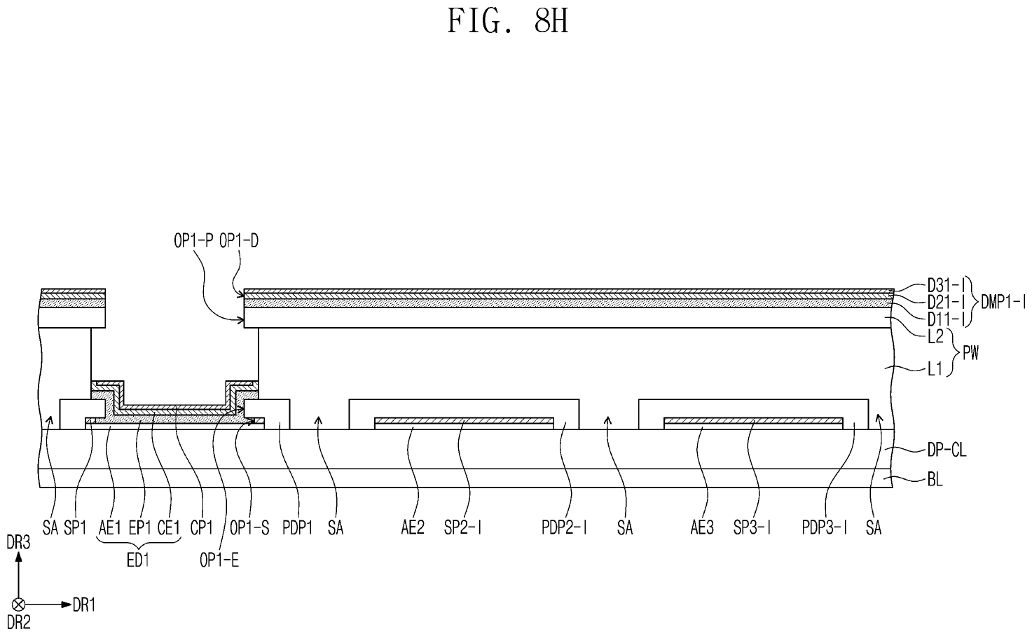

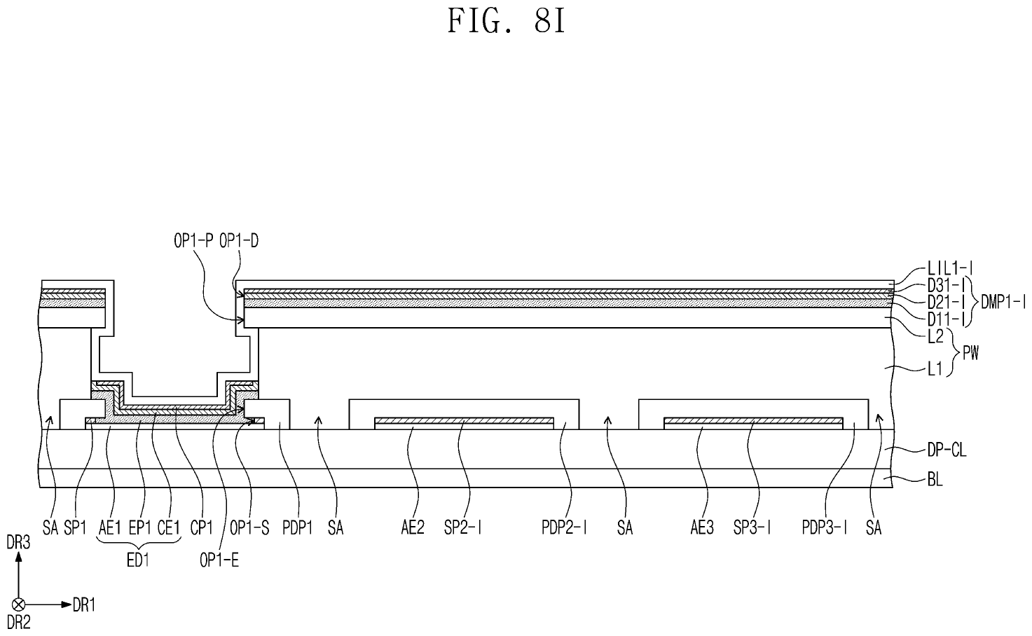

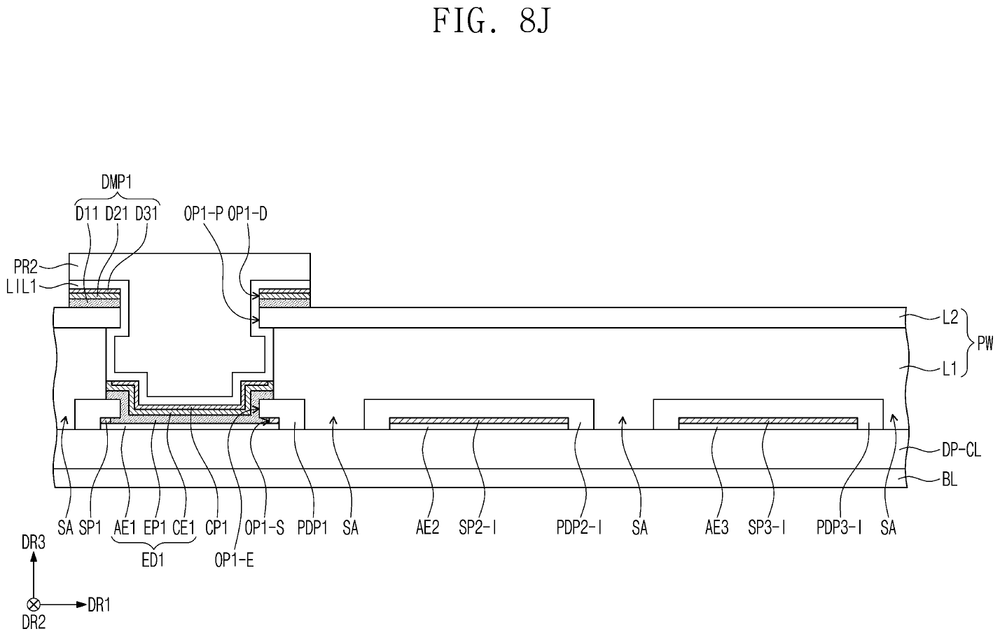

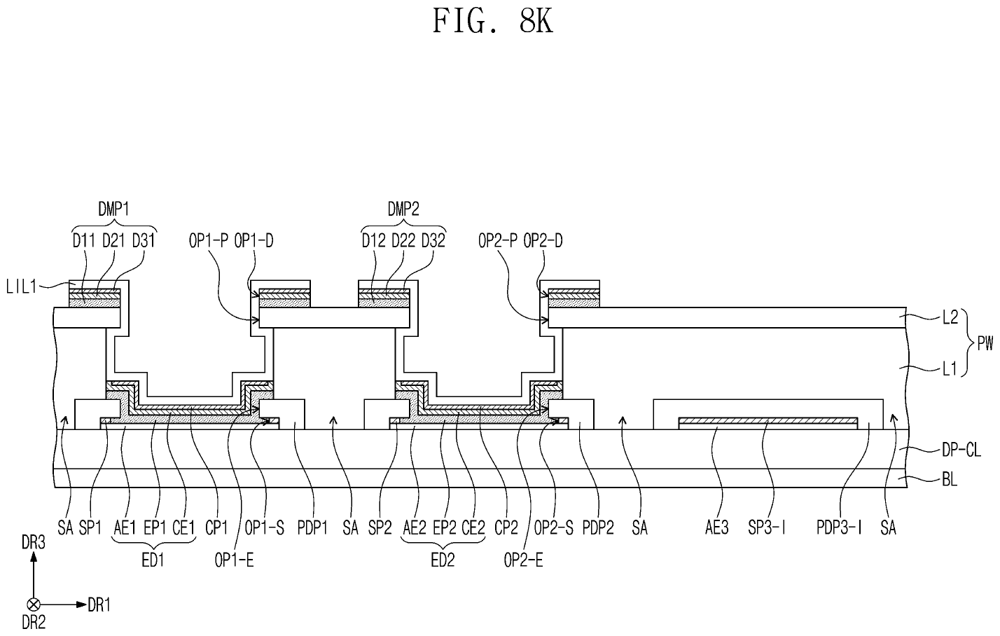

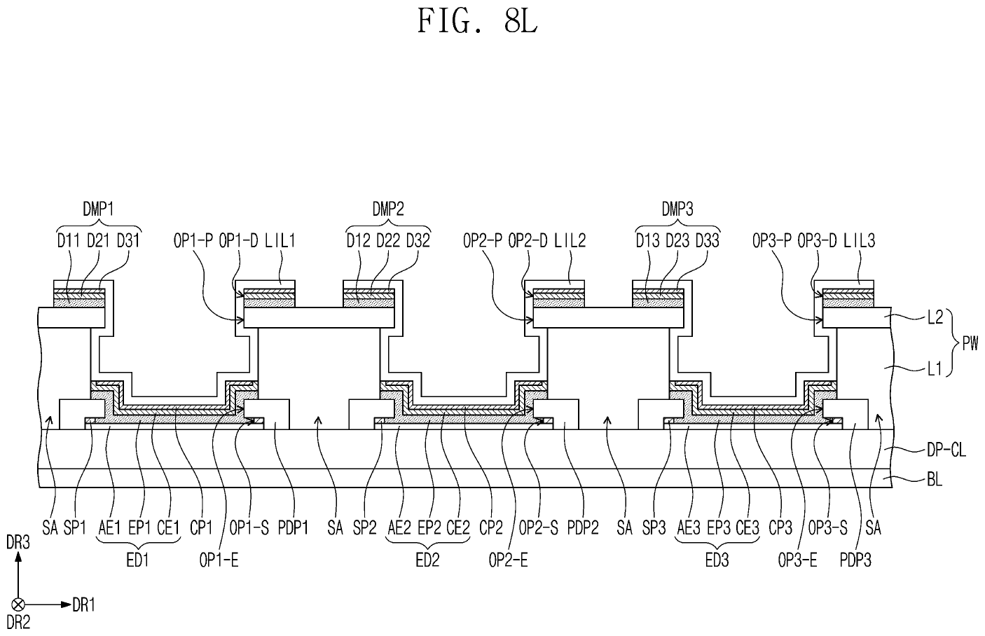

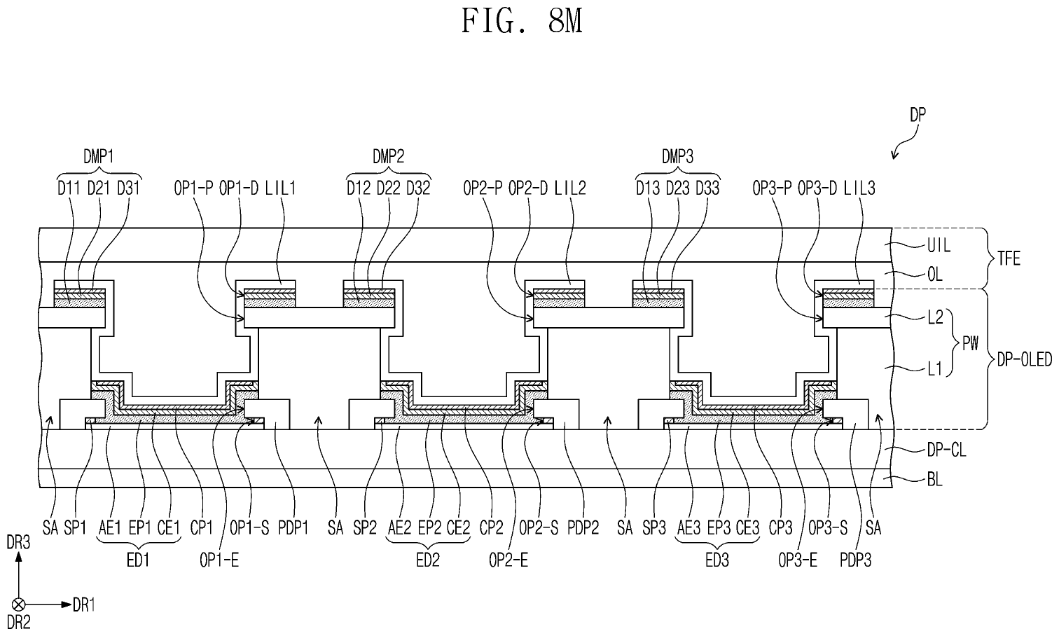

FIGS. 8A to 8M are cross-sectional views illustrating processes of a method of manufacturing (or providing) the display panel DP according to an embodiment of the present disclosure. In description of FIGS. 8A to 8M, the same/similar reference numerals will be used for the same/similar components with reference to FIGS. 1 to 7, and duplicated descriptions thereof will be omitted.

A method of manufacturing (or providing) of a display panel DP according to the present disclosure may include providing a preliminary display panel DP-I including a base layer BL and a first anode AE1, a second anode AE2 and a third anode AE3 disposed on the base layer BL, forming (or providing) a preliminary pixel defining pattern provided in plural including a plurality of preliminary pixel defining patterns that cover the first anode AE1, the second anode AE2 and the third anode AE3 and are spaced apart from each other, forming a preliminary partition wall PW-I that covers the plurality of preliminary pixel defining patterns, etching the preliminary partition wall PW-I to form a partition wall PW in which a plurality of partition wall openings respectively overlapping the plurality of preliminary pixel defining patterns are defined, etching the plurality of preliminary pixel defining patterns to form a plurality of pixel defining patterns PDP in which a plurality of light emitting openings OP-E respectively overlapping the plurality of partition wall openings OP-P are defined, and forming a light emitting pattern EP and a cathode CE in contact with the partition wall PW in each of the plurality of partition wall openings OP-P.

The method of manufacturing (or providing) a display panel DP according to the present disclosure may include a first group process, a second group process, a third group process, and a fourth group process. The first to third group processes may be processes of forming (or providing) the first to third light emitting elements ED1, ED2, and ED3 (see FIG. 8M) and a partial configuration of the thin film encapsulation layer TFE (see FIG. 8M), and the fourth group process may be a process of completing the display panel DP (see FIG. 8M) by forming the other configuration of the thin film encapsulation layer TFE (see FIG. 8M).

In an embodiment, the first light emitting element ED1 (see FIG. 8J) and the first lower encapsulation inorganic pattern LIL1 (see FIG. 8J) for covering the same may be formed through the first group process. Hereinafter, the first group process will be described with reference to FIGS. 8A to 8J.

Referring to FIG. 8A, the method of manufacturing a display panel DP according to an embodiment may include providing a preliminary display panel DP-I. The preliminary display panel DP-I provided in an embodiment may include the base layer BL, the circuit element layer DP-CL, the first to third anodes AE1, AE2, and AE3 in a first conductive layer, and first to third preliminary sacrificial patterns SP1-I, SP2-I, and SP3-I in a sacrificial layer.

The circuit element layer DP-CL may be formed by a general method of manufacturing a circuit element, in which an insulating layer, a semiconductor layer, and a conductive layer are formed through a coating method or a deposition method, the insulating layer, the semiconductor layer, and the conductive layer are selectively patterned by a photolithography and etching process, and a semiconductor pattern, a conductive pattern, a signal line or the like are formed. The first to third anodes AE1, AE2, and AE3 and the first to third preliminary sacrificial patterns SP1-I, SP2-I, and SP3-I may be formed through the same patterning process.

Thereafter, referring to FIG. 8B, the method of manufacturing a display panel DP according to an embodiment may include forming a plurality of preliminary pixel defining patterns PDP1-I, PDP2-I, and PDP3-I and forming a preliminary partition wall PW-I.

The plurality of preliminary pixel defining patterns PDP1-I, PDP2-I, and PDP3-I in a pixel defining layer for covering the first to third anodes AE1, AE2, and AE3, respectively, may be formed. For example, the first preliminary pixel defining pattern PDP1-I may cover the first anode AE1, the second preliminary pixel defining pattern PDP2-I may cover the second anode AE2, and the third preliminary pixel defining pattern PDP3-I may cover the third anode AE3.

The plurality of preliminary pixel defining patterns PDP1-I, PDP2-I, and PDP3-I may be spaced apart from each other in a direction along the circuit element layer DP-CL. The plurality of preliminary pixel defining patterns PDP1-I, PDP2-I, and PDP3-I may be spaced apart from each other in the first direction DR1 and/or the second direction DR2. The separation space SA may be defined respectively between the plurality of preliminary pixel defining patterns PDP1-I, PDP2-I, and PDP3-I which are adjacent to each other.

The preliminary partition wall PW-I in a partition wall layer for covering the plurality of preliminary pixel defining patterns PDP1-I, PDP2-I, and PDP3-I may be formed. The forming of the preliminary partition wall PW-I may include forming a first preliminary partition wall layer L1-I and forming a second preliminary partition wall layer L2-I.

The forming of the first preliminary partition wall layer L1-I may be performed through a process of depositing a conductive material of a second conductive layer. The first preliminary partition wall layer L1-I may cover the plurality of preliminary pixel defining patterns PDP1-I, PDP2-I, and PDP3-I and fill the separation space SA. The forming of the second preliminary partition wall layer L2-I may be performed through a process of depositing a conductive material of a third conductive layer. The second preliminary partition wall layer L2-I may be disposed on the first preliminary partition wall layer L1-I.

Thereafter, Referring to FIG. 8C, the method of manufacturing a display panel DP according to an embodiment may include forming a first photoresist layer PR1 on the preliminary partition wall PW-I. The first photoresist layer PR1 may be formed by forming a preliminary photoresist layer on the preliminary partition wall PW-I and then patterning the preliminary photoresist layer using a photo mask. Through the patterning process, a photo opening OP-PR overlapping or corresponding to the first anode AE1 may be formed in the first photoresist layer PR1. The second preliminary partition wall layer L2-I may be exposed to outside the first photoresist layer PR1 at the photo opening OP-PR.

Thereafter, referring to FIG. 8D and FIG. 8E, the method of manufacturing a display panel DP according to an embodiment may include forming the partition wall PW by etching the preliminary partition wall PW-I to remove a portion thereof which corresponds to the first anode AE1. The forming of the partition wall PW may include etching a portion of the first preliminary partition wall layer L1-I and a portion of the second preliminary partition wall layer L2-I.

As illustrated in FIG. 8D, the primary etching of the first preliminary partition wall layer L1-I and the second preliminary partition wall layer L2-I may include forming a first preliminary partition wall opening OP1-PI in the preliminary partition wall PW-I by using the first photoresist layer PR1 as a mask and dry-etching the first preliminary partition wall layer L1-I and the second preliminary partition wall layer L2-I.

A primary dry etching process in an embodiment may be performed in an etching environment in which an etching selection ratio between the first preliminary partition wall layer L1-I and the second preliminary partition wall layer L2-I is substantially the same. Accordingly, an inner surface of the first preliminary partition wall layer L1-I and an inner surface of the second preliminary partition wall layer L2-I defining the first preliminary partition wall opening OP1-PI may be substantially aligned with each other.

Thereafter, as illustrated in FIG. 8E, the secondary etching of the first preliminary partition wall layer L1-I may include forming the first partition wall opening OP1-P from the first preliminary partition wall opening OP1-PI (see FIG. 8D) by using the first photoresist layer PR1 as a mask and wet-etching the first preliminary partition wall layer L1-I.

The first partition wall opening OP1-P may include the first area A1 representing a first volume and the second area A2 representing a second volume sequentially arranged in a thickness direction (that is, the third direction DR3), in a direction away from the circuit element layer DP-CL. The first partition wall layer L1 may include the first inner surface defining the first area A1 of the first partition wall opening OP1-P, and the second partition wall layer L2 may include the second inner surface defining the second area A2. The first partition wall opening OP1-P as the first area A1 together with the second area A2 may overlap the first preliminary pixel defining pattern PDP1-I.

A secondary wet etching process in an embodiment may be performed in an environment in which the etching selection ratio between the first preliminary partition wall layer L1-I and the second preliminary partition wall layer L2-I is large. Accordingly, the partition wall PW defining the first partition wall opening OP1-P may have an undercut shape on a cross section. In detail, as an etch rate of the first preliminary partition wall layer L1-I with respect to an etching solution is greater than an etch rate of the second preliminary partition wall layer L2-I with respect to the etching solution, the first preliminary partition wall layer L1-I may be mainly etched. Accordingly, the first inner surface of the first partition wall layer L1 may be more recessed inward than the second inner surface of the second partition wall layer L2. The tip portion may be formed in the partition wall PW by a portion of the second partition wall layer L2 which defines the second inner surface protruding from the first partition wall layer L1 which defines the first inner surface.

Thereafter, referring to FIG. 8F, the method of manufacturing a display panel DP according to an embodiment may include etching the first preliminary pixel defining pattern PDP1-I (see FIG. 8E) to form the first pixel defining pattern PDP1 to expose the sacrificial layer to outside the first pixel defining pattern PDP1. The etching of the first preliminary pixel defining pattern PDP1-I may be performed in a dry etching method, and the etching may be performed using the first photoresist layer PR1 and the partition wall PW (for example, the second partition wall layer L2) as a mask. The first light emitting opening OP1-E overlapping the first partition wall opening OP1-P may be defined in the first pixel defining pattern PDP1.

Thereafter, referring to FIG. 8G, the method of manufacturing a display panel DP according to an embodiment may include etching the first preliminary sacrificial pattern SP1-I (see FIG. 8F) to expose a portion of the first anode AE1 to outside the sacrificial layer. The etching of the first preliminary sacrificial pattern SP1-I may be performed in a wet etching method, and the etching may be performed using the first photoresist layer PR1 and the partition wall PW (for example, the second partition wall layer L2) as a mask.

The first sacrificial opening OP1-S overlapping the first light emitting opening OP1-E may be formed in the first sacrificial pattern SP1 formed by etching the first preliminary sacrificial pattern SP1-I. At least a portion of the first anode AE1 may be exposed from the first sacrificial pattern SP1 and from the first pixel defining pattern PDP1 by the first sacrificial opening OP1-S and the first light emitting opening OP1-E, respectively.

The etching of the first sacrificial pattern SP1 may be performed in an environment in which an etching selection ratio between the first sacrificial pattern SP1 and the first anode AE1 is large, and therefore, the first anode AE1 may be prevented from being etched together. That is, as the first sacrificial pattern SP1 having a higher etch rate than that of the first anode AE1 is disposed between the first pixel defining pattern PDP1 and the first anode AE1, the first anode AE1 may be prevented from being etched together and damaged during the etching process.

Thereafter, referring to FIG. 8H, the method of manufacturing a display panel DP according to an embodiment may include forming the first light emitting pattern EP1 after the first photoresist layer PR1 (see FIG. 8G) is removed, forming the first cathode CE1, and forming the first capping pattern CP1.

The forming of the first light emitting pattern EP1, the forming of the first cathode CE1, and the forming of the first capping pattern CP1 may be performed by a deposition process. In an embodiment, the forming of the first light emitting pattern EP1 may be performed by a thermal evaporation process, the forming of the first cathode CE1 may be performed by a sputtering process, and the forming of the first capping pattern CP1 may be performed by the thermal evaporation process. However, the present disclosure is not limited thereto.

In the forming of the first light emitting pattern EP1, a light emitting material layer may be separated or disconnected by providing of the light emitting material layer on the tip portion formed in the partition wall PW. Thus, a pattern of the light emitting layer may be disposed in the first light emitting opening OP1-E and the first partition wall opening OP1-P, thereby providing the first light emitting pattern EP1. In the forming of the first light emitting pattern EP1, a remaining portion of the light emitting material layer provides a (1-1)^{th} dummy layer D11-I spaced apart from the first light emitting pattern EP1 along the partition wall PW. That is, the first light emitting pattern EP1 and the (1-1)^{th} dummy layer D11-I may be formed together with each other, by disconnection of the light emitting material layer by the protruding tip of the partition wall PW.

In the forming of the first cathode CE1, a cathode material layer may be separated or disconnected by providing of the cathode material layer on the tip portion formed in the partition wall PW. Thus, a pattern of the cathode material layer may be disposed in the first partition wall opening OP1-P, thereby providing the first cathode CE1. The first cathode CE1 may be provided at a higher incident angle than that of the first light emitting pattern EP1, and the first cathode CE1 may be formed to be in contact with the first inner surface of the first partition wall layer L1. In the forming of the first cathode CE1, a remaining portion of the cathode material layer provides a (2-1)^{th} dummy layer D21-I spaced apart from the cathode CE1 along the partition wall PW. That is, the first cathode CE1 and the (2-1)^{th} dummy layer D21-I may be formed together with each other, by disconnection of the cathode material layer by the protruding tip of the partition wall PW. The first anode AE1, the first light emitting pattern EP1, and the first cathode CE1 may together constitute the first light emitting element ED1.

In the forming of the first capping pattern CP1, a capping material layer may be separated or disconnected by providing of the capping material layer on the tip portion formed in the partition wall PW. Thus, a pattern of the capping material layer may be disposed in the first partition wall opening OP1-P, thereby defining the first capping pattern CP1. In the forming of the first capping pattern CP1, a remaining portion of the capping material layer provides a (3-1)^{th} dummy layer D31-I spaced apart from the first capping pattern CP1 along the partition wall PW. That is, the first capping pattern CP1 and the (3-1)^{th} dummy layer D31-I may be formed together with each other, by disconnection of the capping material layer by the protruding tip of the partition wall PW. According to an embodiment of the present disclosure, the forming of the first capping pattern CP1 may be omitted.

The (1-1)^{th} to (3-1)^{th} dummy layers D11-I, D21-I, and D31-I may together form a first dummy layer DMP1-I, and the first dummy opening OP1-D may be formed in the first dummy layer DMP1-I.

Thereafter, referring to FIG. 8I, the method of manufacturing a display panel DP according to an embodiment may include forming a first lower encapsulation inorganic film LIL1-I. A lower encapsulation material layer for forming the first lower encapsulation inorganic film LIL1-I may be formed through a deposition process. In an embodiment, the lower encapsulation material layer for forming the first lower encapsulation inorganic film LIL1-I may be formed through a chemical vapor deposition (CVD) process. The lower encapsulation material layer for forming the first lower encapsulation inorganic film LIL1-I may be formed on the partition wall PW and the first cathode CE1, and a portion of the first lower encapsulation inorganic film LIL1-I may be formed inside the first partition wall opening OP1-P.

Thereafter, referring to FIG. 8J, the method of manufacturing a display panel DP according to an embodiment may include forming a second photoresist layer PR2, patterning the first lower encapsulation inorganic film LIL1-I (see FIG. 8I) to form the first lower encapsulation inorganic pattern LIL1, and patterning the first dummy layer DMP1-I (see FIG. 8I) to form the first dummy patterns DMP1.

In the forming of the second photoresist layer PR2, the second photoresist layer PR2 may be formed by forming a preliminary photoresist layer, and then patterning the preliminary photoresist layer using a photo mask. Through the patterning process, the second photoresist layer PR2 may be formed in a pattern form corresponding to the first light emitting opening OP1-E.

In the patterning of the first lower encapsulation inorganic film LIL1-I, the first lower encapsulation inorganic film LIL1-I may be patterned to remove, through a dry etching process, a portion of the first lower encapsulation inorganic film LIL1-I which overlaps the second and third anodes AE2 and AE3 except for the portion corresponding to the first anode AE1. The first lower encapsulation inorganic pattern LIL1 overlapping the first light emitting opening OP1-E may be formed from the patterned first lower encapsulation inorganic film LIL1-I. A portion of the first lower encapsulation inorganic pattern LIL1 may be disposed inside the first partition wall opening OP1-P to cover the first light emitting element ED1, and the other portion as a remaining portion of the first lower encapsulation inorganic pattern LIL1 may be disposed on the partition wall PW.

In the pattern of the first dummy layer DMP1-I, the (1-1)^{th} to (3-1)^{th} dummy layers D11-I, D21-I, and D31-I may be patterned to remove, through a dry etching process, portions of the (1-1)^{th} to (3-1)^{th} dummy layers D11-I, D21-I, and D31-I, which overlap the second and third anodes AE2 and AE3 except for the first anode AE1. The (1-1)^{th} to (3-1)^{th} dummy patterns D11, D21, and D31 overlapping the first light emitting opening OP1-E are formed from the patterned (1-1)^{th} to (3-1)^{th} dummy layers D11-I, D32-I, and D31-I, and thus the first dummy patterns DMP1 including the (1-1)^{th} to (3-1)^{th} dummy patterns D11, D21, and D31 may be formed. The (1-1)^{th} to (3-1)^{th} dummy patterns D11, D21, and D31 may have a closed-line shape that surrounds the first light emitting area PXA-R (see FIG. 5) on a plane.

After the first group process, the second group process may be performed. Referring to FIG. 8K, the second light emitting element ED2 and the second lower encapsulation inorganic pattern LIL2 covering the same may be formed through the second group process. The process of forming the second light emitting element ED2 and the second lower encapsulation inorganic pattern LIL2 may be substantially the same as the process of forming the first light emitting element ED1 and the first lower encapsulation inorganic pattern LIL1, which is described in FIGS. 8A to 8J. Thus, a description of the second group process will be omitted.

After the second group process, the third group process may be performed. Referring to FIG. 8L, the third light emitting element ED3 and the third lower encapsulation inorganic pattern LIL3 covering the same may be formed through the third group process. The process of forming the third light emitting element ED3 and the third lower encapsulation inorganic pattern LIL3 may be substantially the same as the process of forming the first light emitting element ED1 and the first lower encapsulation inorganic pattern LIL1, which is described in FIGS. 8A to 8J. Thus, a description of the third group process will be omitted.

After the first to third light emitting elements ED1, ED2, and ED3 and the first to third lower encapsulation inorganic patterns LIL1, LIL2, and LIL3 are formed through the first to third group processes, the fourth group process may be performed. The display panel DP (see FIG. 8M) including the thin film encapsulation layer TFE (see FIG. 8M) may be completed through the fourth group process.

Referring to FIG. 8M, the method of manufacturing a display panel DP may include forming the encapsulation organic film OL, on the partition wall PW and the first to third lower encapsulation inorganic patterns LIL1, LIL2, and LIL3 and forming the upper encapsulation inorganic film UIL on the encapsulation organic film OL. Therefore, the display panel DP including the base layer BL, the circuit element layer DP-CL, the display element layer DP-OLED, and the thin film encapsulation layer TFE may be formed.

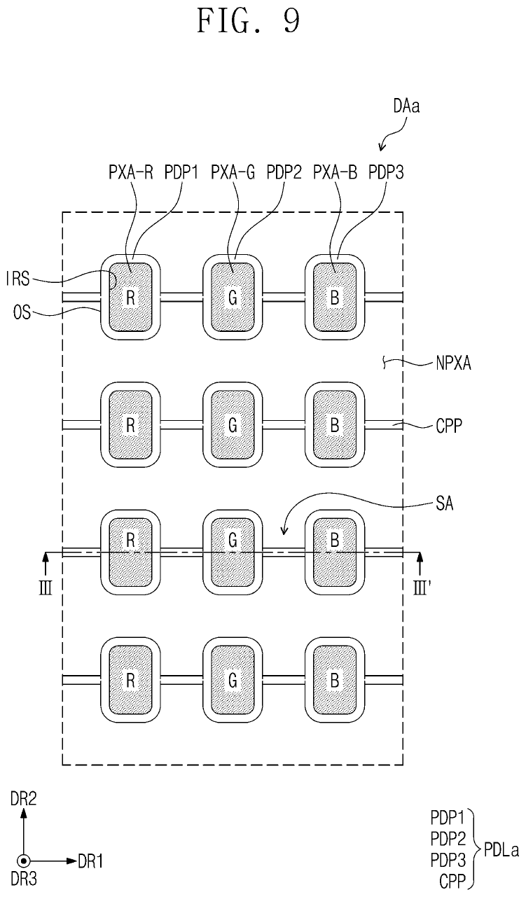

FIG. 9 is an enlarged plan view of a portion of a display area DAa of the display panel DP (see FIG. 2) according to an embodiment of the present disclosure. FIG. 9 illustrates a plan view of the display module DM when viewed from the display surface IS (see FIG. 1B) of the display module DM (see FIG. 1B) and illustrates the light emitting areas PXA-R, PXA-G, and PXA-B and a pixel defining film PDLa. FIG. 9 is described with reference to FIG. 5, and the descriptions of components having the same reference numerals will be omitted.

Referring to FIG. 9, the pixel defining film PDLa may be positioned on the peripheral area NPXA. The pixel defining film PDLa may include the plurality of pixel defining patterns PDP1, PDP2, and PDP3 which are spaced apart from each other, and a connection pattern CPP provided in plural including a plurality of connection patterns CPP which are spaced apart from each other.

When viewed on a plane, the first pixel defining pattern PDP1, the second pixel defining pattern PDP2, and the third pixel defining pattern PDP3 may surround the corresponding light emitting areas PXA-R, PXA-G, and PXA-B, respectively. The plurality of pixel defining patterns PDP1, PDP2, and PDP3 may be spaced apart from each other in the first direction DR1 and the second direction DR2.

The plurality of connection patterns CPP may connect a group of pixel defining patterns PDP1, PDP2, and PDP3 which are spaced apart from each other and connected to each other along a direction. Referring to FIG. 9, for example, the connection patterns CPP may connect the group of pixel defining patterns PDP1, PDP2, and PDP3 spaced apart from each other in the first direction DR1, to each other. However, this is illustrative, the plurality of connection patterns CPP may connect adjacent patterns among the plurality of pixel defining patterns PDP1, PDP2, and PDP3 which are spaced apart from each other in the second direction DR2 to each other, or the plurality of connection patterns CPP may connect the group of pixel defining patterns PDP1, PDP2, and PDP3 which are spaced apart from each other in the first direction DR1 and the second direction DR2 respectively to each other. The plurality of connection patterns CPP may include the same material as that of the plurality of pixel defining patterns PDP1, PDP2, and PDP3 and may be formed through the same process as that of the plurality of pixel defining patterns PDP1, PDP2, and PDP3.

According to the present disclosure, as the plurality of connection patterns CPP connect the plurality of pixel defining patterns PDP1, PDP2, and PDP3 spaced apart from each other, the plurality of pixel defining patterns PDP1, PDP2, and PDP3 may be prevented from being separated from the circuit element layer DP-CL (see FIG. 7).

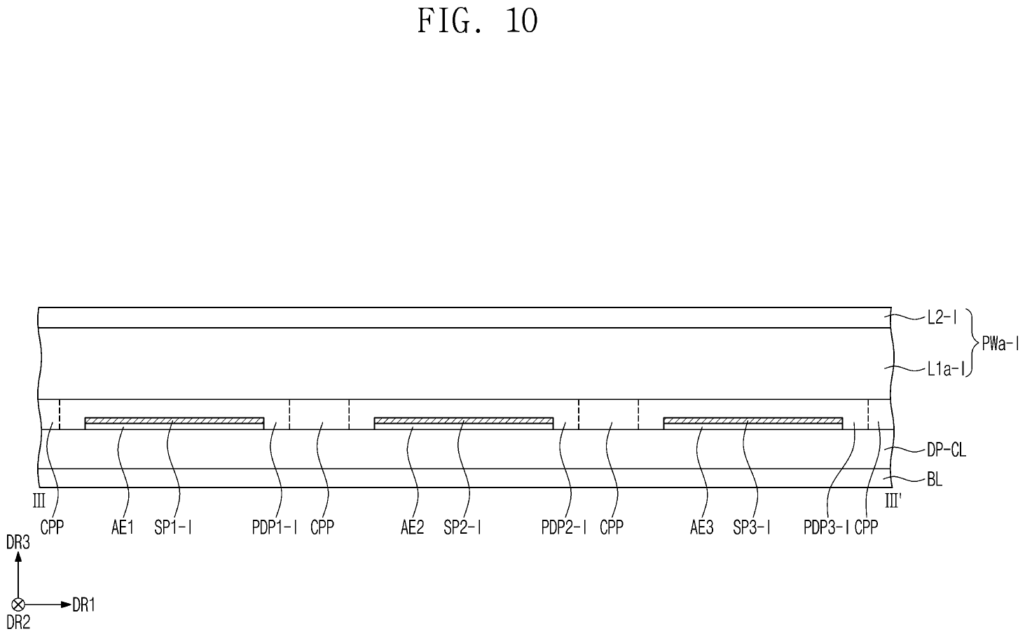

FIG. 10 is a cross-sectional view of some of operations of the method of manufacturing the display panel along line III-III′ of FIG. 9. FIG. 10 mayillustrate substantially the same operation as that of FIG. 8B. In description of FIG. 10, the description will be made with reference to FIG. 8B, and descriptions for the same reference numerals will be omitted.

Referring to FIG. 10, the method of manufacturing a display panel DP according to an embodiment may include forming the plurality of preliminary pixel defining patterns PDP1-I, PDP2-I, and PDP3-I, forming the plurality of connection patterns CPP, and forming a preliminary partition wall PWa-I.

The plurality of preliminary pixel defining patterns PDP1-I, PDP2-I, and PDP3-I for covering the first to third anodes AE1, AE2, and AE3, respectively, may be formed, and the plurality of connection patterns CPP for connecting the plurality of preliminary pixel defining patterns PDP1-I, PDP2-I, and PDP3-I may be formed. The plurality of connection patterns CPP may include the same material as that of the plurality of preliminary pixel defining patterns PDP1-I, PDP2-I, and PDP3-I and may be formed through the same process as that of the plurality of preliminary pixel defining patterns PDP1-I, PDP2-I, and PDP3-I. That is, the plurality of connection patterns CPP may form interfaces with (virtual) sidewalls of the respective pixel defining pattern (see the dotted line in FIG. 10), such that the pixel defining film PDLa is a continuous, unitary layer.

Taking FIGS. 9 and 10, together with FIGS. 5-7, even where the plurality of connection patterns CPP connects groups of pixel defining patterns PDP to each other, a portion of the upper surface of the fifth insulating layer 50 is exposed to outside the pixel defining film PDLa. As such, the gas generated in the fifth insulating layer 50 is not blocked by the pixel defining film PDLa and may be easily discharged at the exposed portion of the fifth insulating layer 50. Thus, as the gas generated during a process is easily discharged, a lifetime of the pixel PX may increase.

The preliminary partition wall PWa-I for covering the plurality of preliminary pixel defining patterns PDP1-I, PDP2-I, and PDP3-I and the plurality of connection patterns CPP may be formed. The forming of the preliminary partition wall PWa-I may include forming a first preliminary partition wall layer L1a-I and forming the second preliminary partition wall layer L2-I.

The forming of the first preliminary partition wall layer L1a-I may be performed through a process of depositing a conductive material. The first preliminary partition wall layer L1a-I may be formed to cover the plurality of preliminary pixel defining patterns PDP1-I, PDP2-I, and PDP3-I and the plurality of connection patterns CPP. The forming of the second preliminary partition wall layer L2-I may be performed through a process of depositing a conductive material. The second preliminary partition wall layer L2-I may be disposed on the first preliminary partition wall layer L1a-I.

As described above, as a pixel defining film PDL includes a plurality of pixel defining patterns PDP spaced apart from each other, the pixel defining film PDL may not cover a front surface of a fifth insulating layer 50 of a circuit element layer DP-CL. The gas generated in the fifth insulating layer 50 maynot be blocked by the pixel defining film PDL and may be easily discharged. Thus, as the gas generated during a process is easily discharged, a lifetime of the pixel PX may increase.

Further, as a plurality of connection patterns CPP connect the plurality of pixel defining patterns PDP spaced apart from each other, the plurality of pixel defining patterns PDP may be prevented from being separated from the circuit element layer.

Although the description has been made above with reference to an embodiment of the present disclosure, it may be understood that those skilled in the art or those having ordinary knowledge in the art may variously modify and changes the present disclosure without departing from the spirit and technical scope of the present disclosure described in the appended claims. Accordingly, the technical scope of the present disclosure is not limited to the detailed description of the specification, but should be defined by the appended claims.

What is claimed is:

1. A display panel comprising:
a base layer;
a pixel defining layer disposed on the base layer and including a plurality of pixel defining patterns spaced apart from each other;
a partition wall which is disposed on the base layer and of which at least a portion covers a portion of each of the plurality of pixel defining patterns; and
a light emitting element including an anode, a light emitting pattern, and a cathode in contact with the partition wall,
wherein a partition wall opening overlapping the anode is defined in the partition wall, and the light emitting pattern and the cathode are arranged in the partition wall opening.

2. The display panel of claim 1, wherein the plurality of pixel defining patterns are arranged spaced apart from each other in a first direction and a second direction which intersects the first direction.

3. The display panel of claim 2, wherein
a separation space is defined between the plurality of pixel defining patterns, and
the partition wall fills the separation space.

4. The display panel of claim 1, wherein one pixel defining pattern among the plurality of pixel defining patterns surrounds the anode.

5. The display panel of claim 4, wherein the one pixel defining pattern includes:
an inner surface which overlaps the anode of the light emitting element, and
an outer surface which is opposite to the inner surface and does not overlap the anode.

6. The display panel of claim 1, wherein the pixel defining layer includes a plurality of connection patterns which respectively connect the plurality of pixel defining patterns to each other.

7. The display panel of claim 6, wherein the plurality of connection patterns and the plurality of pixel defining patterns are respective patterns of a same material layer.

8. The display panel of claim 1, wherein the partition wall includes:
a first partition wall layer which is on the plurality of pixel defining patterns and defines a first area of the partition wall opening; and
a second partition wall layer which is on the first partition wall layer and defines a second area of the partition wall opening, the second partition wall layer being further from the plurality of pixel defining patterns than the first partition wall layer.

9. The display panel of claim 8, wherein
the partition wall has an undercut shape defined by the first partition wall layer together with the second partition wall layer, and
the cathode of the light emitting element is electrically connected to the partition wall at the first partition wall layer.

10. The display panel of claim 1, wherein the pixel defining layer includes an inorganic material.

11. A method of providing a display panel, the method comprising:
providing a preliminary display panel including a base layer and a first anode, a second anode, and a third anode disposed on the base layer;
forming a plurality of preliminary pixel defining patterns configured to cover the first anode, the second anode, and the third anode and spaced apart from each other;
forming a preliminary partition wall configured to cover the plurality of preliminary pixel defining patterns;
etching the preliminary partition wall to form a partition wall in which a plurality of partition wall openings respectively overlapping the plurality of preliminary pixel defining patterns are defined;
etching the plurality of preliminary pixel defining patterns to form a plurality of pixel defining patterns in which a plurality of light emitting openings respectively overlapping the plurality of partition wall openings are defined; and
forming a light emitting pattern and a cathode in contact with the partition wall in each of the plurality of partition wall openings.

12. The method of claim 11, wherein
the plurality of preliminary pixel defining patterns include a first preliminary pixel defining pattern, a second preliminary pixel defining pattern, and a third preliminary pixel defining pattern, the first preliminary pixel defining pattern covers the first anode, the second preliminary pixel defining pattern covers the second anode, and the third preliminary pixel defining pattern covers the third anode.

13. The method of claim 11, wherein the plurality of preliminary pixel defining patterns spaced apart from each other in a first direction and a second direction which intersects the first direction.

14. The method of claim 11, wherein
a separation space is defined between the plurality of preliminary pixel defining patterns, and
the providing of the preliminary partition wall includes:
providing a first preliminary partition wall layer covering the plurality of preliminary pixel defining patterns and filling the separation space; and
providing a second preliminary partition wall layer on the first preliminary partition wall layer.

15. The method of claim 11, further comprising:
providing a plurality of connection patterns configured to connect the plurality of preliminary pixel defining patterns,
wherein the plurality of connection patterns include the same material as that of the plurality of preliminary pixel defining patterns and are provided through a same process as that of the plurality of preliminary pixel defining patterns.

16. A display panel comprising:
a pixel defining layer including a plurality of pixel defining patterns spaced apart from each other with a separation space therebetween, each of the pixel defining patterns defining a light emitting opening of the pixel defining layer;
a partition wall which is on the pixel defining layer and fills the separation space between the plurality of pixel defining patterns spaced apart from each other, the partition wall defining a partition wall opening corresponding to the light emitting opening of the pixel defining layer; and
a light emitting element including an anode, a light emitting pattern and a cathode,
wherein the cathode of the light emitting element is in the partition wall opening and is electrically connected to the partition wall.

17. The display panel of claim 16, wherein a pixel defining pattern among the plurality of pixel defining patterns has a closed curve shape surrounding the anode.

18. The display panel of claim 16, wherein the pixel defining layer further includes a connection pattern which connects the plurality of pixel defining patterns to each other.

19. The display panel of claim 18, wherein the connection pattern and the plurality of pixel defining patterns are respective patterns of a same material layer.

20. The display panel of claim 16, wherein the pixel defining layer includes an inorganic material.
